(19) United States
(12) Patent Application Publication
(10) Pub. No.: US 2018/0209039 A1
(43) Pub. Date: Jul. 26, 2018

(54) VAPOR DEPOSITION METHOD AND VAPOR DEPOSITION DEVICE

(71) Applicant: Sharp Kabushiki Kaisha, Sakai City, Osaka (JP)

(72) Inventors: Takashi OCHI, Sakai City (JP); Shinichi KAWATO, Sakai City (JP); Kazuki MATSUNAGA, Sakai City (JP); Yuhki KOBAYASHI, Sakai City (JP); Katsuhiro KIKUCHI, Sakai City (JP); Masahiro ICHIHARA, Mitsuke-shi (JP)

(21) Appl. No.: 15/743,705

(22) PCT Filed: Jul. 13, 2016
(86) PCT No.: PCT/JP2016/070682

§ 371 Date: Jan. 11, 2018

(30) Foreign Application Priority Data
Jul. 15, 2015 (JP) 2015-141553

(51) Int. Cl. C23C 16/04; C23C 16/455; C23C 14/04; C23C 14/24; C23C 14/12; H01L 51/00; H01L 51/56

(52) U.S. Cl. CPC C23C 16/042; C23C 16/45563; C23C 14/042; H01L 51/56; C23C 14/12; H01L 51/0011; H01L 51/001; C23C 14/24

(57) ABSTRACT

Limit nozzles configured to restrict directivity of first, second and third vapor deposition particles discharged from first, second and third vapor deposition source openings toward a substrate in an in-plane direction are installed in the first, second and third vapor deposition source openings.

### TECHNICAL FIELD

Several aspects of the present invention relate to a vapor deposition method and a vapor deposition device that are configured to form a coat having a predetermined pattern on a substrate. In addition, several aspects of the present invention relate to an appropriate technology used in manufacturing of an organic electro luminescence (EL) display device including a light emitting layer formed by vapor deposition.

Priority is claimed on Japanese Patent Application No. 2015-141553, filed Jul. 15, 2015, the content of which is incorporated herein by reference.

### BACKGROUND ART

For example, an organic EL display device (display) including organic EL elements may be provided as an active matrix type, and in the organic EL display device, organic EL elements having a thin film shape may be formed on a substrate on which thin film transistors (TFTs) are formed. In the organic EL element, an organic EL layer including a light emitting layer is deposited between a pair of electrodes. A TFT is connected to one of the pair of electrodes. Then, image display is performed by applying a voltage between the pair of electrodes and causing the light emitting layer to emit light.

In a full color organic EL display device, in general, organic EL elements including light emitting layers having colors of red (R), green (G) and blue (B) are formed by being arranged on the substrate as sub-pixels. Color image display is performed by selectively causing some of the organic EL elements to emit light with a desired luminance using the TFTs.

In manufacturing of an organic EL display device, a light emitting layer constituted by organic light emitting materials that emit colored light is formed on each of the organic EL elements in a predetermined pattern using a vacuum vapor deposition method.

In the vacuum vapor deposition method, a mask (also referred to as a shadow mask) in which openings having a predetermined pattern are formed is used. A surface to be vapor-deposited of the substrate to which the mask is adhered and fixed faces a vapor deposition source. Then, as vapor deposition particles (a film forming material) from the vapor deposition source are vapor-deposited on the surface to be vapor-deposited through the opening of the mask, a coat having a predetermined pattern is formed. Vapor deposition is performed on each color of light emitting layer (this is also referred to as “coating vapor deposition”).

Different layers are vapor-deposited using a metal mask (a fine metal mask: FMM) in which opening sections are precisely formed in the mask. Here, as disclosed in Patent Document 1, scanning (scanning) type vapor deposition (scanning vapor deposition) of performing vapor deposition while relatively moving and scanning a film deposition substrate (a film deposition target) and a mask unit and a vapor deposition source using a vapor deposition mask having a size smaller than the film deposition substrate is known.

In addition, all the vapor deposition particles are not directed in the same direction normal to the substrate, and film forming may be performed in a state in which the vapor deposition particles are at an angle from the direction normal to the substrate to a substrate in-plane direction. A technology of making an arrangement pitch of vapor deposition source openings constant in order to ameliorate non-uniformity in the density of the vapor deposition particles with respect to a direction perpendicular to the substrate conveyance direction is disclosed in Patent Document 2.

### PRIOR ART DOCUMENTS

### Patent Documents

[Patent Document 1] PCT International Publication No. 2014/010284 [Patent Document 2] Japanese Unexamined Patent Application, First Publication No. 2004-095275

[Patent Document 3] PCT International Publication No. 2012/098927

### SUMMARY OF THE INVENTION

### Problem to be Solved by the Invention

However, since Patent Document 2 is a technology related to a vapor deposition technique configured to form a film on a relatively large area using an open mask, while the density distribution of the particles that reach the substrate can be controlled to a certain extent in the direction perpendicular to the substrate conveyance direction, an incident angle of the vapor deposition particles is not controlled. In this case, spreading of a vapor deposition pattern cannot be suppressed, and precise coating cannot be realized.

Moreover, as disclosed in Patent Document 3, in manufacturing of a light emitting device on which a film is formed through co-vapor deposition by scanning vapor deposition, when openings of the vapor deposition sources are disposed at different positions in the substrate conveyance direction, since a host, an assist and a dopant supplied by three different vapor deposition sources have different film thickness distributions in the substrate conveyance direction, a concentration ratio of three materials may be different according to a film forming position in the substrate conveyance direction.

In addition, in Patent Document 3, while the second vapor deposition source and the third vapor deposition source can be disposed to be inclined with respect to each other to make the film thickness distributions in the substrate conveyance direction uniform, it is extremely difficult to make the film thickness distribution in the substrate conveyance direction uniform simply with this inclination, because the film thickness on an extension line in each inclination direction is largest.

In particular, when a mask having at least two rows of openings in the substrate conveyance direction is used, since the openings of the vapor deposition sources in the vapor deposition region of a front row and the vapor deposition region of a rear row in which film forming is performed are disposed at different positions in the substrate conveyance direction, differences in density (concentration) of the vapor deposition material occur between a film formed at the front row and a film formed at the rear row. When a film formed at the front row and a film formed at the rear row are formed as neighboring vapor deposition regions continuous in the lateral direction, eventually, due to non-uniformity of the density (concentration), a boundary due to a difference in chromaticity/luminance may be visually checked in the film formed by the front row portion and the rear row portion. Accordingly, in the vapor deposition regions that initially need to be uniform in a light emitting device having a film formed through co-vapor deposition by scanning vapor deposition, a boundary may be visually recognizable due to small differences in luminance or chromaticity, and a vapor deposition technique capable of appropriately preventing such problems does not yet exist.

In consideration of the above-mentioned circumstances, some aspects of the present invention have been accomplished to provide a vapor deposition method and a vapor deposition device capable of realizing film formation in which a ratio between the host, the assist and the dopant is constant regardless of a position in the substrate conveyance direction, eliminating differences in chromaticity/luminance at a boundary between vapor deposition regions in the light emitting device, and forming a film having a precise pattern with good productivity, in a state in which a spreading angle of the vapor deposition particles is restricted and the film thickness distribution of the host, the assist and the dopant is constant in the substrate conveyance direction, in manufacturing of a light emitting device in which the film is formed through co-vapor deposition by scanning vapor deposition.

### Means for Solving the Problems

A vapor deposition device according to one aspect of the present invention solves the above-described problem by the vapor deposition device comprising:

a vapor deposition unit having a plurality of vapor deposition sources each having a vapor deposition source opening configured to perform co-vapor deposition with respect to at least the mask opening; and

a moving mechanism configured to relatively move one of the substrate and the vapor deposition unit with respect to the other in a first direction which is an in-plane direction of the substrate,

wherein the plurality of vapor deposition source openings are disposed at different positions from an upstream side in the first direction,

limit nozzles configured to restrict directivity to the in-plane direction of a plurality of vapor deposition particles discharged from the plurality of vapor deposition source openings toward the substrate are installed in the plurality of vapor deposition source openings,

at least a region in which the plurality of vapor deposition particles overlap in a vapor deposition region is provided with respect to the vapor deposition region on the substrate to which the plurality of vapor deposition particles adhere in a case that the vapor deposition mask is not provided, and

the limit nozzles are set to restrict the directivity of the vapor deposition particles in the first direction to reduce differences in density distribution of the vapor deposition particles in the vapor deposition region generated due to the positions of the limit nozzles in the first direction.

The vapor deposition device according to one aspect of the present invention solves the above-described problem by that the plurality of vapor deposition sources comprise first, second and third vapor deposition sources, and the first, second and third vapor deposition sources include first, second and third vapor deposition source openings,

the third, first and second vapor deposition source openings are sequentially disposed at different positions from an upstream side toward a downstream side in the first direction,

first, second and third limit nozzles configured to restrict directivity of first, second and third vapor deposition particles discharged from the first, second and third vapor deposition source openings toward the substrate in the in-plane direction are installed in the first, second and third vapor deposition source openings,

provided that regions on the substrate to which the first vapor deposition particles, the second vapor deposition particles and the third vapor deposition particles adhere are a first region, a second region and a third region, respectively, in a case that the vapor deposition mask is not provided,

discharge directions of the second and third vapor deposition particles are controlled to be inclined to have portions of the first, second and third vapor deposition source openings in which the first region, the second region and the third region overlap each other,

the second limit nozzle reduces the second vapor deposition particles density that is large at the first limit nozzle side of the second region in the first direction by inclining the discharge direction of the second vapor deposition particles toward the first limit nozzle such that the second region overlaps the first region, and reduces a difference of the second vapor deposition particles density in the second region in the first direction and restrict the directivity to decrease a width of the distribution,

the third limit nozzle reduces the third vapor deposition particles density that is large at the first limit nozzle side of the third region in the first direction by inclining the discharge direction of the third vapor deposition particles toward the first limit nozzle such that the third region overlaps the first region, and reduces a difference of the third vapor deposition particles density of the third region in the first direction and restrict the directivity to reduce a width of the distribution,

the first limit nozzle installed in the first vapor deposition source opening restricts the directivity to reduce a difference of the distribution of the first vapor deposition particles that is reduced at an upstream side and a downstream side in the first direction in the first region, and

in the first, second and third limit nozzles, directivity of the first, second and third vapor deposition particles is set to be restricted such that a distribution state of the first, second and third vapor deposition particles density is equalized in the first direction.

It is preferable that the limit nozzle according to one aspect of the present invention is set to restrict the directivity of the first to third vapor deposition particles in the first direction such that positions of the first to third region in the first direction coincide with each other.

In one aspect of the present invention, any one of the first limit nozzle installed in the first vapor deposition source opening, the second limit nozzle installed in the second vapor deposition source opening, and the third limit nozzle installed in the third vapor deposition source opening may be disposed by being separated into plural sections in the first direction.

The plurality of first to third divided limit nozzles according to one aspect of the present invention may be disposed irregularly in the first direction.

The limit nozzles according to one aspect of the present invention may be that the limit nozzles vary sizes of nozzle openings divided in plural by the second limit nozzle at positions in the first direction, are set to restrict the directivity of the second vapor deposition particles to correct a density distribution inclined toward the first vapor deposition source openings adjacent to each other in the first direction in the second region, vary sizes of the nozzle openings divided in plural by the third limit nozzle at positions in the first direction, are set to restrict the directivity of the third vapor deposition particles to correct a density distribution inclined toward the first vapor deposition source openings adjacent to each other in the first direction in the third region, vary sizes of the nozzle openings divided in plural by the first limit nozzle at positions in the first direction, and are set to restrict the directivity of the first vapor deposition particles to correct a density distribution inclined toward the second and third vapor deposition source openings adjacent to each other from a center in the first direction in the first region.

A vapor deposition method according to one aspect of the present invention has a vapor deposition process of attaching vapor deposition particles onto a substrate and forming a coat having a predetermined pattern, wherein the vapor deposition process may be performed using the above-described vapor deposition device.

One aspect of the present invention may be that the vapor deposition process is performed using the above-described vapor deposition device, and

the coat includes a portion in which the first vapor deposition particles, the second vapor deposition particles and the third vapor deposition particles are mixed.

The vapor deposition method according to one aspect of the present invention may be that the vapor deposition process is performed using the above-described vapor deposition device, and

in the coat, a mixing ratio of the first vapor deposition particles, the second vapor deposition particles and the third vapor deposition particles is constant in the first direction.

The coat may be a light emitting layer of an organic EL element.

A vapor deposition device according to one aspect of the present invention comprises:

a vapor deposition unit having a plurality of vapor deposition sources each having a vapor deposition source opening configured to perform co-vapor deposition with respect to at least the mask opening; and

a moving mechanism configured to relatively move one of the substrate and the vapor deposition unit with respect to the other in a first direction which is an in-plane direction of the substrate,

wherein the plurality of vapor deposition source openings are disposed at different positions from an upstream side in the first direction,

limit nozzles configured to restrict directivity to the in-plane direction of a plurality of vapor deposition particles discharged from the plurality of vapor deposition source openings toward the substrate are installed in the plurality of vapor deposition source openings,

at least a region in which the plurality of vapor deposition particles overlap in a vapor deposition region is provided with respect to the vapor deposition region on the substrate to which the plurality of vapor deposition particles adhere in a case that the vapor deposition mask is not provided, and

the limit nozzles are set to restrict the directivity of the vapor deposition particles in the first direction to reduce differences in density distribution of the vapor deposition particles in the vapor deposition region generated due to the positions of the limit nozzles in the first direction. Therefore, when a plurality kinds of vapor deposition particles reach the substrate to form the coat through co-vapor deposition, in a state in which the spreading angle of the vapor deposition particles is restricted, variation in distribution of the vapor deposition particles, which are host/assist/dopant, in the substrate conveyance direction is avoided and the film thickness distribution due to the vapor deposition particles is uniform in the first direction, film formation in which the host/assist/dopant ratio is constant regardless of the position in the substrate conveyance direction can be realized, and differences in chromaticity/luminance at the boundary between the vapor deposition regions in the light emitting device can be eliminated.

In the vapor deposition device according to one aspect of the present invention, the plurality of vapor deposition sources comprise first, second and third vapor deposition sources, and the first, second and third vapor deposition sources include first, second and third vapor deposition source openings,

the third, first and second vapor deposition source openings are sequentially disposed at different positions from an upstream side toward a downstream side in the first direction,

first, second and third limit nozzles configured to restrict directivity of first, second and third vapor deposition particles discharged from the first, second and third vapor deposition source openings toward the substrate in the in-plane direction are installed in the first, second and third vapor deposition source openings,

provided that regions on the substrate to which the first vapor deposition particles, the second vapor deposition particles and the third vapor deposition particles adhere are a first region, a second region and a third region, respectively, in a case that the vapor deposition mask is not provided,

discharge directions of the second and third vapor deposition particles are controlled to be inclined to have portions of the first, second and third vapor deposition source openings in which the first region, the second region and the third region overlap each other,

the second limit nozzle reduces the second vapor deposition particles density that is large at the first limit nozzle side of the second region in the first direction by inclining the discharge direction of the second vapor deposition particles toward the first limit nozzle such that the second region overlaps the first region, and reduces a difference of the second vapor deposition particles density in the second region in the first direction and restrict the directivity to decrease a width of the distribution,

the third limit nozzle reduces the third vapor deposition particles density that is large at the first limit nozzle side of the third region in the first direction by inclining the discharge direction of the third vapor deposition particles toward the first limit nozzle such that the third region overlaps the first region, and reduces a difference of the third vapor deposition particles density of the third region in the first direction and restrict the directivity to reduce a width of the distribution,

the first limit nozzle installed in the first vapor deposition source opening restricts the directivity to reduce a difference of the distribution of the first vapor deposition particles that is reduced at an upstream side and a downstream side in the first direction in the first region, and in the first, second and third limit nozzles, directivity of the first, second and third vapor deposition particles is set to be restricted such that a distribution state of the first, second and third vapor deposition particles density is equalized in the first direction. Therefore, when first to third vapor deposition particles reach the substrate to form the coat through co-vapor deposition, in a state in which the spreading angle of the vapor deposition particles is restricted, variation in distribution of the vapor deposition particles, which are host/assist/dopant, in the substrate conveyance direction is avoided and the film thickness distribution due to the vapor deposition particles is uniform in the first direction, film formation in which the ratio is constant regardless of the position in the substrate conveyance direction can be realized, and differences in chromaticity/luminance at the boundary between the vapor deposition regions in the light emitting device can be eliminated.

The limit nozzle according to one aspect of the present invention is set to restrict the directivity of the first to third vapor deposition particles in the first direction such that positions of the first to third region in the first direction coincide with each other. Therefore, it is possible to realize film formation in which a distribution is constant in the substrate conveyance direction by restricting the directivity of each of the vapor deposition particles in the co-vapor deposition in which the first to third regions are overlapped at the substrate in-plane position, and by reducing, at a necessary portion, a variation of the distribution of the vapor deposition particles in the first direction.

In one aspect of the present invention, any one of the first limit nozzle installed in the first vapor deposition source opening, the second limit nozzle installed in the second vapor deposition source opening, and the third limit nozzle installed in the third vapor deposition source opening may be disposed by being separated into plural sections in the first direction. Therefore, it is possible to realize film formation in which the distribution of the vapor deposition particles is constant in the substrate conveyance direction by respectively optimizing the distribution in the first direction for each of the vapor deposition particles discharged from each limit nozzle.

The plurality of first to third divided limit nozzles according to one aspect of the present invention may be disposed irregularly in the first direction. Therefore, it is possible to realize film formation in which the distribution of the vapor deposition particles is constant in the substrate conveyance direction by optimizing the distribution in the first direction for each of the vapor deposition particles.

Specifically, in the setting in the second limit nozzle provided at the second vapor deposition source opening, a high density state in which a density of the second vapor deposition particles is larger at a side of the first vapor deposition source opening than at a center of the first direction is reduced. Then, a nozzle shape is set such that a density distribution of the second vapor deposition particles becomes flat in the first direction in the second region.

Similarly, in the setting in the third limit nozzle provided at the third vapor deposition source opening, a high density state in which a density of the third vapor deposition particles is larger at a side of the first vapor deposition source opening than at a center of the first direction is reduced. Then, a nozzle shape is set such that a density distribution of the third vapor deposition particles becomes flat in the first direction in the third region.

In the setting of the first limit nozzle provided at the first vapor deposition source opening, it is possible to restrict the directivity of the first vapor deposition particles such that a density distribution of the first vapor deposition particles becomes flat in the first direction in the first region by reducing a high density state near the center where the number of the vapor deposition particles becomes largest for a side of the second vapor deposition source opening and a side of the third vapor deposition source opening adjacent each other in the first direction of the first region in line with the density distribution of the second vapor deposition particles and the third vapor deposition particles set by the second limit nozzle and the third limit nozzle.

The limit nozzles according to one aspect of the present invention may be that the limit nozzles vary sizes of nozzle openings divided in plural by the second limit nozzle at positions in the first direction, are set to restrict the directivity of the second vapor deposition particles to correct a density distribution inclined toward the first vapor deposition source openings adjacent to each other in the first direction in the second region, vary sizes of the nozzle openings divided in plural by the third limit nozzle at positions in the first direction, are set to restrict the directivity of the third vapor deposition particles to correct a density distribution inclined toward the first vapor deposition source openings adjacent to each other in the first direction in the third region, vary sizes of the nozzle openings divided in plural by the first limit nozzle at positions in the first direction, and are set to restrict the directivity of the first vapor deposition particles to correct a density distribution inclined toward the second and third vapor deposition source openings adjacent to each other from a center in the first direction in the first region. Therefore, it is possible to realize film formation in which a distribution of the vapor deposition particles becomes nearly the same in the substrate conveyance direction by optimizing the distribution in the first direction of each of the vapor deposition particles.

A vapor deposition method according to one aspect of the present invention has a vapor deposition process of attaching vapor deposition particles onto a substrate and forming a coat having a predetermined pattern, wherein the vapor deposition process may be performed using the above-described vapor deposition device.

Therefore, when co-vapor deposition which is a multi-source vapor deposition is performed by using a scanning vapor deposition and when the first to third vapor deposition particles reach the substrate to form the coat through co-vapor deposition, in a state in which the spreading angle of the vapor deposition particles is restricted, variation in distribution of the vapor deposition particles in the first direction is avoided and the film thickness distribution due to the vapor deposition particles, which are host/assist/dopant, is uniform in the substrate conveyance direction, film formation in which the host/assist/dopant ratio is constant regardless of the position of the mask opening in the substrate conveyance direction can be realized without depending on the position of the film formation, and differences in chromaticity/luminance at the boundary between the vapor deposition regions in the light emitting device can be eliminated.

In the one aspect of the present invention, the vapor deposition process is performed by using the any one of the above-described vapor deposition devices.

The coat may include the portion in which the first vapor deposition particles, the second vapor deposition particles and the third vapor deposition particles are mixed. A mixing ratio of the first vapor deposition particles, the second vapor deposition particles and the third vapor deposition particles may be constant in the first direction. Therefore, it is possible to realize the co-vapor deposition of three sources as uniformed density distribution in the first direction.

### Effect of the Invention

According to several aspects of the present invention, when the vapor deposition particles reach the substrate to form the coat through co-vapor deposition, in a state in which the spreading angle of the vapor deposition particles is restricted, variation in distribution of the vapor deposition particles in the first direction is avoided and the film thickness distribution due to the vapor deposition particles is uniform in the first direction, film formation in which the ratio is constant regardless of the position in the substrate conveyance direction can be realized, and differences in chromaticity/luminance at the boundary between the vapor deposition regions in the light emitting device can be eliminated.

### BRIEF DESCRIPTION OF DRAWINGS

FIG. 1 is a cross-sectional view showing a schematic configuration of an organic EL display device.

FIG. 2 is a plan view showing a configuration of pixels that constitute the organic EL display device shown in FIG. 1.

FIG. 3 is a cross-sectional view of a TFT substrate that constitutes the organic EL display device taken along line in FIG. 2.

FIG. 4 is a flowchart showing a process of manufacturing the organic EL display device in sequence of processes.

FIG. 5 is a front cross-sectional view showing an aspect in which a coat 90 is formed on a substrate 10 along a surface parallel to a moving direction 10a of the substrate 10, as a view along a surface passing through a vapor deposition source opening perpendicular to a running direction of a substrate of a vapor deposition device according to the first embodiment of the present invention.

FIG. 6 is a cross-sectional view showing the vapor deposition source opening of the vapor deposition device shown in FIG. 5.

FIG. 7 is a plan view showing the vapor deposition mask opening of the vapor deposition device as a plan view showing the vapor deposition mask opening of the vapor deposition device shown in FIG. 5.

FIG. 8 is graphs showing setting conditions of the vapor deposition source opening of the vapor deposition device shown in FIG. 6, FIG. 8(a) showing a graph of a film thickness distribution in a substrate conveyance direction due to the vapor deposition source opening of the embodiment, FIG. 8(b) showing a graph of a standardized film thickness distribution in the substrate conveyance direction due to the vapor deposition source opening of the embodiment, and FIG. 8(c) showing a graph showing a standardized film thickness distribution in a substrate conveyance direction by a vapor deposition source opening in the related art.

FIG. 9 is a front cross-sectional view along a surface parallel to a moving direction 10a of a substrate 10 showing an aspect in which a coat 90 is formed on the substrate 10, as a view along a surface passing through a vapor deposition source opening perpendicular to a running direction of a substrate of a vapor deposition device according to a second embodiment of the present invention.

FIG. 10 is a cross-sectional view showing the vapor deposition source opening of the vapor deposition device shown in FIG. 9.

FIG. 11 is a plan view showing a vapor deposition mask opening of the vapor deposition device shown in FIG. 9.

FIG. 12 is graphs showing setting conditions of the vapor deposition source opening of the vapor deposition device shown in FIG. 10, FIG. 12(a) showing a graph of a film thickness distribution in a substrate conveyance direction due to the vapor deposition source opening of the embodiment, FIG. 12(b) showing a graph of a standardized film thickness distribution in the substrate conveyance direction due to the vapor deposition source opening of the embodiment, and FIG. 12(c) showing a graph showing a standardized film thickness distribution in a substrate conveyance direction by a vapor deposition source opening in the related art.

FIG. 13 is a front cross-sectional view along a surface passing through a vapor deposition source opening perpendicular to a running direction of a substrate of a vapor deposition device according to a third embodiment of the present invention.

FIG. 14 is a plan view showing a vapor deposition source opening and a limit nozzle of the vapor deposition device shown in FIG. 13.

FIG. 15 is a plan view showing a vapor deposition mask opening of the vapor deposition device shown in FIG. 13.

FIG. 16 is graphs showing setting conditions of the vapor deposition source opening of the vapor deposition device shown in FIG. 14, FIG. 16(a) showing a graph of a film thickness distribution in a substrate conveyance direction due to the vapor deposition source opening of the embodiment, FIG. 16(b) showing a graph of a standardized film thickness distribution in the substrate conveyance direction due to the vapor deposition source opening of the embodiment, and FIG. 16(c) showing a graph of a standardized film thickness distribution in a substrate conveyance direction by a vapor deposition source opening in the related art.

FIG. 17 is a front cross-sectional view showing another configuration example of a limit nozzle of the vapor deposition device according to the embodiment of the present invention.

### EMBODIMENTS FOR CARRYING OUT THE INVENTION

Hereinafter, a first embodiment of a vapor deposition method and a vapor deposition device according to the present invention will be described with reference to the accompanying drawings.

However, it is needless to say that the present invention is not limited to the following embodiments. For the convenience of description, the drawings referred to in the following description are views simply showing only primary members required for describing the embodiments of the present invention in components of the embodiments of the present invention. Accordingly, the embodiments of the present invention may include arbitrary components that are not shown in the following drawings. In addition, dimensions of members in the following drawings may be not a faithful representation of dimensions of the actual components, a dimensional ratio between members, and so on.

### (Configuration of Organic EL Display Device)

An example of an organic EL display device that can be manufactured by applying the embodiments of the present invention will be described. The organic EL display device of the example is an organic EL display device, which is a bottom emission type in which light is extracted from a TFT substrate side, configured to perform image display in full color by controlling emission of pixels (sub-pixels) formed for the colors of red (R), green (G) and blue (B).

First, the entire configuration of the organic EL display device will be described below.

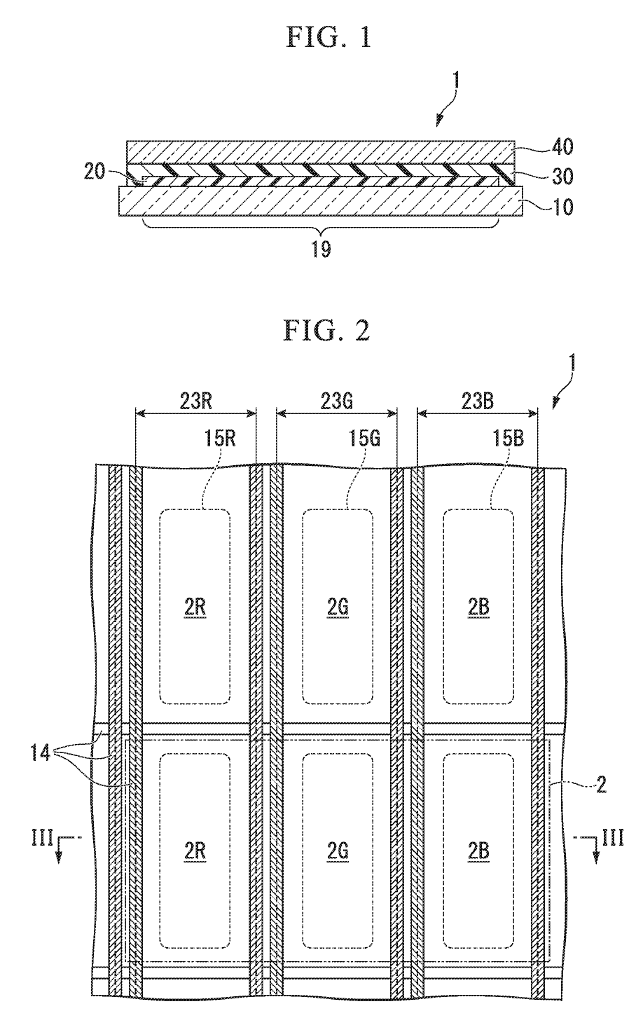

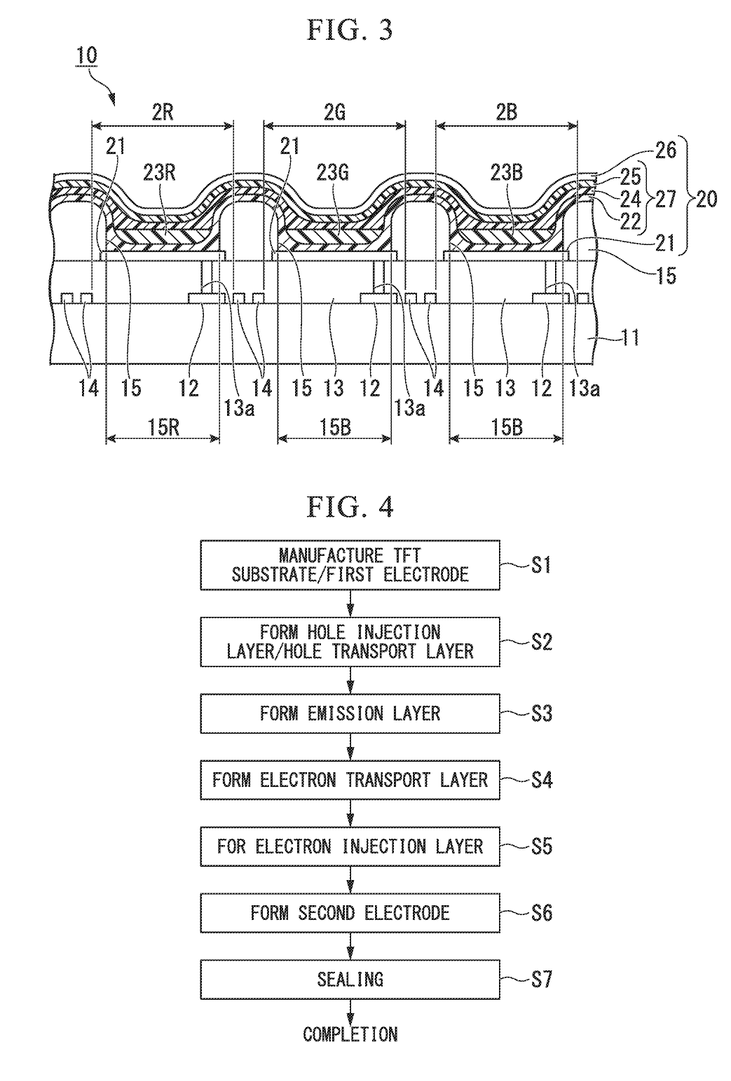

FIG. 1 is a cross-sectional view showing a schematic configuration of the organic EL display device. FIG. 2 is a plan view showing a configuration of pixels that constitute the organic EL display device shown in FIG. 1. FIG. 3 is a cross-sectional view of a TFT substrate that constitutes the organic EL display device taken along line III-III in FIG. 2.

As shown in FIG. 1, an organic EL display device 1 has a configuration in which an organic EL element 20, an adhesion layer 30 and a sealing substrate 40 that are connected to TFTs 12 are sequentially formed on a TFT substrate 10 on which TFTs 12 (see FIG. 3) are formed. A center of the organic EL display device 1 is a display region 19 in which image display is performed, and the organic EL element 20 is disposed in the display region 19.

The organic EL element 20 is sealed between the pair of substrates 10 and 40 by bonding the TFT substrate 10 on which the organic EL element 20 is stacked to the sealing substrate 40 using the adhesion layer 30. In this way, as the organic EL element 20 is sealed between the TFT substrate 10 and the sealing substrate 40, intrusion of oxygen or moisture into the organic EL element 20 from the outside is prevented.

As shown in FIG. 3, the TFT substrate 10 includes a transparent insulating substrate 11 such as a glass substrate or the like serving as a support substrate. However, in a top emission organic EL display device, an insulating substrate 11 may not be transparent.

As shown in FIG. 2, a plurality of interconnections 14 constituted by a plurality of gate lines laid in a horizontal direction and a plurality of signal lines laid in a vertical direction and crossing the gate lines are formed on the insulating substrate 11. A gate line drive circuit (not shown) configured to drive the gate lines is connected to the gate lines, and a signal line drive circuit (not shown) configured to drive the signal lines is connected to the signal lines. Sub-pixels 2R, 2G and 2B constituted by the organic EL elements 20 having colors of red (R), green (G) and blue (B) are disposed on the insulating substrate 11 in regions surrounded by the interconnections 14 in a matrix.

The sub-pixel 2R emits red light, the sub-pixel 2G emits green light, and the sub-pixel 2B emits blue light. Sub-pixels having the same color are disposed in a column direction (an upward/downward direction in FIG. 2), and repeating units constituted by the sub-pixels 2R, 2G and 2B are repeatedly disposed in a row direction (a leftward/rightward direction in FIG. 2). The sub-pixels 2R, 2G and 2B constituting a repeating unit in the row direction constitute a pixel 2 (i.e., one pixel).

The sub-pixels 2R, 2G and 2B include light emitting layers 23R, 23G and 23B configured to emit colors, respectively. The light emitting layers 23R, 23G and 23B are formed to extend in the column direction (the upward/downward direction in FIG. 2) in a stripe shape.

A configuration of the TFT substrate 10 will be described.

As shown in FIG. 3, the TFT substrate 10 includes the TFTs 12 (a switching element), the interconnections 14, an interlayer film 13 (an interlayer insulating film, a flattening film), an edge cover 15, and so on, installed on the transparent insulating substrate 11 such as a glass substrate or the like.

The TFT 12 functions as a switching element configured to control emission of the sub-pixels 2R, 2G and 2B, and is installed on each of the sub-pixels 2R, 2G and 2B. The TFT 12 is connected to the interconnections 14.

The interlayer film 13 functions as a flattening film, and is deposited on the entire surface of the display region 19 on the insulating substrate 11 to cover the TFTs 12 and the interconnections 14.

A first electrode 21 is formed on the interlayer film 13. The first electrode 21 is electrically connected to the TFT 12 via a contact hole 13a formed in the interlayer film 13.

The edge cover 15 is formed on the interlayer film 13 to cover a pattern end portion of the first electrode 21. The edge cover 15 is an insulating layer configured to prevent a short circuit of the first electrode 21 and a second electrode 26 that constitute the organic EL element 20 when an organic EL layer 27 becomes thinned or an electric field concentration occurs in the pattern end portion of the first electrode 21.

Openings 15R, 15G and 15B are formed on the edge cover 15 at the sub-pixels 2R, 2G and 2B, respectively. The openings 15R, 15G and 15B of the edge cover 15 are emission regions of the sub-pixels 2R, 2G and 2B. In other words, the sub-pixels 2R, 2G and 2B are partitioned by the edge cover 15 having an insulation property. The edge cover 15 also functions as an element separating film.

The organic EL element 20 will be described.

The organic EL element 20 is a light emitting element that enables high luminance emission by low voltage direct current driving, and includes the first electrode 21, the organic EL layer 27 and the second electrode 26 in sequence.

The first electrode 21 is a layer having a function of injecting (supplying) holes into the organic EL layer 27. The first electrode 21 is connected to the TFT 12 via the contact hole 13a as described above.

As shown in FIG. 3, the organic EL layer 27 includes a hole injection layer and hole transport layer 22, the light emitting layers 23R, 23G and 23B, an electron transport layer 24 and an electron injection layer 25 in sequence between the first electrode 21 and the second electrode 26 from the first electrode 21 side.

While the first electrode 21 is a positive electrode and the second electrode 26 is a negative electrode in the embodiment, the first electrode 21 may be a negative electrode and the second electrode 26 may be a positive electrode, and in this case, a sequence of the layers that constitute the organic EL layer 27 is reversed.

The hole injection layer and hole transport layer 22 has both of a function as a hole injection layer and a function as a hole transport layer. The hole injection layer is a layer having a function of increasing a hole injection efficiency with respect to the organic EL layer 27. The hole transport layer is a layer having a function of increasing a hole transport efficiency with respect to the light emitting layers 23R, 23G and 23B.

The hole injection layer and hole transport layer 22 is evenly formed on the entire surface of the display region 19 in the TFT substrate 10 to cover the first electrodes 21 and the edge cover 15.

While the hole injection layer and hole transport layer 22 in which the hole injection layer and the hole transport layer are integrated is formed in the embodiment, the present invention is not limited thereto and the hole injection layer and the hole transport layer may be formed as layers independent from each other.

The light emitting layers 23R, 23G and 23B are formed on the hole injection layer and hole transport layer 22 correspondingly to the rows of the sub-pixels 2R, 2G and 2B to cover the openings 15R, 15G and 15B of the edge cover 15, respectively. The light emitting layers 23R, 23G and 23B are layers having a function of recombining the holes injected from the first electrode 21 side and the electrons injected from the second electrode 26 side and emitting light. Each of the light emitting layers 23R, 23G and 23B includes a material having high emission efficiency such as a low-molecular-weight fluorescent dye, a metal complex, or the like.

The electron transport layer 24 is a layer having a function of increasing an electron transport efficiency from the second electrode 26 to the light emitting layers 23R, 23G and 23B.

The electron injection layer 25 is a layer having a function of increasing an electron injection efficiency from the second electrode 26 to the organic EL layer 27.

The electron transport layer 24 is evenly formed on the light emitting layers 23R, 23G and 23B and the hole injection layer and hole transport layer 22 throughout the surface of the display region 19 in the TFT substrate 10 to cover the light emitting layers 23R, 23G and 23B and the hole injection layer and hole transport layer 22. In addition, the electron injection layer 25 is evenly formed on the electron transport layer 24 throughout the surface of the display region 19 in the TFT substrate 10 to cover the electron transport layer 24.

While the electron transport layer 24 and the electron injection layer 25 are formed as layers independent from each other in the embodiment, the present invention is not limited thereto and the electron transport layer 24 and the electron injection layer 25 may be formed as a single layer in which both layers are integrated (i.e., an electron transport layer and electron injection layer).

The second electrode 26 is a layer having a function of injecting electrons into the organic EL layer 27. The second electrode 26 is formed on the electron injection layer 25 throughout the surface of the display region 19 in the TFT substrate 10 to cover the electron injection layer 25.

Further, an organic layer other than the light emitting layers 23R, 23G and 23B may not be the organic EL layer 27 and may be appropriately selected according to required characteristics of the organic EL element 20. In addition, the organic EL layer 27 may further have a carrier blocking layer according to necessity. For example, when a hole blocking layer serving as a carrier blocking layer is added between the light emitting layers 23R, 23G and 23B and the electron transport layer 24, escape of holes to the electron transport layer 24 is minimized, and emission efficiency can be improved.

### (Method of Manufacturing Organic EL Display Device)

Next, a method of manufacturing the organic EL display device 1 will be described below.

FIG. 4 is a flowchart showing processes of manufacturing the organic EL display device 1 in sequence.

As shown in FIG. 4, the method of manufacturing the organic EL display device 1 according to the embodiment includes, for example, a process S1 of fabricating a TFT substrate/a first electrode, a process S2 of forming a hole injection layer/a hole transport layer, a process S3 of forming a light emitting layer, a process S4 of forming an electron transport layer, a process S5 of forming an electron injection layer, a process S6 of forming a second electrode, and a sealing process S7, in sequence.

Hereinafter, processes of FIG. 4 will be described. However, the dimensions, materials, shapes, and the like, of the components shown below are merely examples, and the present invention is not limited thereto. In addition, in the embodiment, the first electrode 21 is the positive electrode and the second electrode 26 is the negative electrode, but on the other hand, when the first electrode 21 is a negative electrode and the second electrode 26 is the positive electrode, a deposition sequence of the organic EL layer is reversed from the following description. Similarly, the materials that constitute the first electrode 21 and the second electrode 26 are also inverted from that in the following description.

Initially, the TFT 12, the interconnections 14, and so on, are formed on the insulating substrate 11 through a known method. For example, a transparent glass substrate, a plastic substrate, or the like, may be used as the insulating substrate 11. A rectangular glass plate having a thickness of about 1 mm and longitudinal and lateral dimensions of 500×400 mm may be used as an example of the insulating substrate 11.

Next, the interlayer film 13 is formed by applying a photosensitive resin on the insulating substrate 11 to cover the TFTs 12 and the interconnections 14 and performing patterning using a photolithography technology. For example, an insulating material such as an acryl resin, a polyimide resin, or the like, may be used as the material of the interlayer film 13. However, a polyimide resin is generally not transparent and is colored. For this reason, when the bottom emission type organic EL display device 1 as shown in FIG. 3 is manufactured, a transparent resin such as an acryl resin or the like may be used as the interlayer film 13. A thickness of the interlayer film 13 is not particularly limited as long as a step difference in an upper surface of the TFT 12 can be eliminated. In the example, the interlayer film 13 having a thickness of about 2 μm may be formed using an acryl resin.

Next, the contact holes 13a configured to electrically connect the first electrodes 21 to the TFTs 12 are formed in the interlayer film 13.

Next, the first electrodes 21 are formed on the interlayer film 13. That is, a conductive film (an electrode film) is formed on the interlayer film 13. Next, after applying photoresist on a conductive film and performing patterning using a photolithography technology, the conductive film is etched using ferric chloride as an etchant. After that, the photoresist is delaminated using a resist peeling liquid, and further, the substrate is cleaned. Accordingly, the first electrodes 21 having a matrix form are obtained on the interlayer film 13.

A transparent conductive material such as indium tin oxide (ITO), indium zinc oxide (IZO), GZO (zinc oxide with added gallium), or the like, or a metal material such as gold (Au), nickel (Ni), platinum (Pt), or the like, may be used as a conductive film material used in the first electrode 21.

A sputtering method, a vacuum vapor deposition method, a chemical vapor deposition (CVD) method, a plasma CVD method, a printing method, or the like, may be used as a deposition method of a conductive film. A first electrode 21 having a thickness of about 100 nm may be formed using ITO as an example through a sputtering method.

Next, the edge cover 15 having a predetermined pattern is formed. For example, the same insulating materials as for the interlayer film 13 may be used for the edge cover 15, and the patterning may be performed through the same method as the interlayer film 13. In the example, the edge cover 15 having a thickness of about 1 μm may be formed using an acryl resin.

The TFT substrate 10 and the first electrode 21 are fabricated as described above (the process S1).

Next, the TFT substrate 10 having passed through the process S1 is baked at a low pressure and dehydrated, and further, oxygen plasma processing is performed to wash the surface of the first electrode 21.

Next, a hole injection layer and hole transport layer (in the embodiment, the hole injection layer and hole transport layer 22) is formed on the TFT substrate 10 throughout the surface of the display region 19 of the TFT substrate 10 through a vapor deposition method (S2).

Specifically, a material for the hole injection layer and hole transport layer is vapor-deposited on the entire surface of the display region 19 of the TFT substrate 10 through openings of an open mask while closely fixing the open mask in which the entire surface of the display region 19 is open to the TFT substrate 10 and rotating the TFT substrate 10 and the open mask together.

The hole injection layer and the hole transport layer may be integrated as described above or may be layers independent from each other. A thickness of each of the layers may be, for example, 10 to 100 nm.

For example, benzine, styrylamines, triphenylamines, porphyrins, triazole, imidazole, oxadiazole, polyarylalkanes, phenylenediamines, arylamines, oxazole, anthracene, fluorenone, hydrazones, stilbene, triphenylene, azatriphenylene, and derivatives thereof, heterocyclic or conjugated chain monomers, oligomers, polymers, or the like, such as polysilane-based compounds, vinylcarbazole-based compounds, thiophene-based compounds, and aniline-based compounds, or the like, may be exemplified as materials of the hole injection layer and the hole transport layer.

In the example, a hole injection layer and hole transport layer 22 having a thickness of 30 nm may be formed using 4,4′-bis[N-(1-naphthyl)-N-phenylamino]biphenyl (α-NPD).

Next, the light emitting layers 23R, 23G and 23B are formed on the hole injection layer and hole transport layer 22 in a stripe shape to cover the openings 15R, 15G and 15B of the edge cover 15 (S3).

The light emitting layers 23R, 23G and 23B are vapor-deposited such that predetermined regions are coated differently according to colors of red, green and blue (“coating vapor deposition”).

A material having high emission efficiency such as a low-molecular-fluorescent dye, a metal complex, or the like, is used as the material of the light emitting layers 23R, 23G and 23B. For example, anthracene, naphthalene, indene, phenanthrene, pyrene, naphthacene, triphenylene, anthracene, perylene, picene, fluoranthene, acephenanthrylene, pentaphene, pentacene, coronene, butadiene, coumarin, acridine, stilbene, and derivatives thereof, tris(8-quinolinolato)aluminum complexes, bis(benzquinolinolato)beryllium complexes, tri(dibenzoylmethyl)phenanthroline europium complexes, ditoluyl vinylbiphenyl, or the like, may be exemplified.

The light emitting layers 23R, 23G and 23B may be constituted by only the above-mentioned organic light emitting materials, or may include a hole transport layer material, an electron transport layer material, additives (a donor, an acceptor or the like), a luminescent dopant, or the like. In addition, a configuration in which these materials are dispersed in a polymer material (a binding resin) or an inorganic material may be provided. From a viewpoint of improvement in emission efficiency and an increase in lifetime, a luminescent dopant is dispersed in a host.

The luminescent dopant is not particularly limited and a known dopant material may be used. For example, aromatic dimethylidene derivatives such as 4,4′-bis(2,2′-diphenylvinyl)-biphenyl (DPVBi), 4,4′-bis[2-{4-(N,N-diphenylamino)phenyl}vinyl]biphenyl (DPAVBi), or the like, coumarin derivatives such as styryl derivatives, perylene, iridium complexes, coumarin 6, or the like, Lumogen F Red, dicyanomethylenepyran, phenoxazone, porphyrin derivatives, or the like, may be exemplified. Further, when kinds of dopant are appropriately selected, a red light emitting layer 23R that emits red color, a green light emitting layer 23G that emits green color, and a blue light emitting layer 23B that emits blue color are formed.

For example, the same materials as the materials that form the light emitting layers 23R, 23G and 23B, carbazole derivatives, or the like, may be exemplified as a host material that is a dispersion medium of the luminescent dopant.

When a light emitting layer in which a dopant is dispersed in a host is formed, while a content of the dopant with respect to the host is not particularly limited and may be appropriately changed according to the materials thereof, the content of the dopant is preferably generally several % to 30%.

A thickness of the light emitting layers 23R, 23G and 23B may be, for example, 10 to 100 nm.

The vapor deposition method and the vapor deposition device according to some aspects of the present invention can be particularly appropriately used in “coating vapor deposition” of the light emitting layers 23R, 23G and 23B. A method of forming the light emitting layers 23R, 23G and 23B using one aspect of the present invention will be described in detail later.

Next, the electron transport layer 24 is formed on the entire surface of the display region 19 of the TFT substrate 10 to cover the hole injection layer and hole transport layer 22 and the light emitting layers 23R, 23G and 23B through the vapor deposition method (S4). The electron transport layer 24 may be formed by the same method as in the process S2 of forming the hole injection layer/hole transport layer.

Next, the electron injection layer 25 is formed on the entire surface of the display region 19 of the TFT substrate 10 to cover the electron transport layer 24 through the vapor deposition method (S5). The electron injection layer 25 may be formed by the same method as in the process S2 of forming the hole injection layer/hole transport layer.

For example, quinoline, perylene, phenanthroline, bisstyryl, pyrazine, triazole, oxazole, oxadiazole, fluorenone, and derivatives thereof, metal complexes, LiF (lithium fluoride), or the like, may be used as the material of the electron transport layer 24 and the electron injection layer 25.

As described above, the electron transport layer 24 and the electron injection layer 25 may be formed as an integrated single layer or may be independent layers. A thickness of each layer is, for example, 1 to 100 nm. In addition, a total thickness of the electron transport layer 24 and the electron injection layer 25 is, for example, 20 to 200 nm.

In the example, the electron transport layer 24 having a thickness of 30 nm may be formed using Alq (tris(8-hydroxyquinoline)aluminum), and the electron injection layer 25 having a thickness of 1 nm may be formed using LiF (lithium fluoride).

Next, the second electrode 26 is formed on the entire surface of the display region 19 of the TFT substrate 10 to cover the electron injection layer 25 through the vapor deposition method (S6). The second electrode 26 may be formed by the same method as in the process S2 of forming the hole injection layer/hole transport layer. A metal or the like having a small work function is appropriately used as a material (an electrode material) of the second electrode 26. For example, a magnesium alloy (MgAg or the like), an aluminum alloy (AlLi, AlCa, AlMg, or the like), metallic calcium, or the like, may be exemplified as such an electrode material. A thickness of the second electrode 26 is, for example, 50 to 100 nm. In the example, the second electrode 26 having a thickness of 50 nm may be formed using aluminum.

In order to prevent intrusion of oxygen or moisture into the organic EL element 20 from the outside, a protective film may be further formed on the second electrode 26 to cover the second electrode 26. A material having an insulation property or conductivity may be used as the material of the protective film, and for example, silicon nitride or silicon oxide may be exemplified. A thickness of the protective film is, for example, 100 to 1000 nm.

As described above, the organic EL element 20 constituted by the first electrode 21, the organic EL layer 27 and the second electrode 26 may be formed on the TFT substrate 10.

Next, as shown in FIG. 1, the organic EL element 20 is sealed by bonding the TFT substrate 10 on which the organic EL element 20 is formed to the sealing substrate 40 using the adhesion layer 30. For example, an insulating substrate such as a glass substrate having a thickness of 0.4 to 1.1 mm, a plastic substrate, or the like, may be used as the sealing substrate 40. Thus, the organic EL display device 1 is obtained.

In the organic EL display device 1, when the TFT 12 is turned ON by a signal input from the interconnections 14, holes are injected from the first electrode 21 into the organic EL layer 27. Meanwhile, electrons are injected from the second electrode 26 into the organic EL layer 27. The holes and the electrons are recombined in the light emitting layers 23R, 23G and 23B, and light having predetermined colors is emitted due to energy deactivation. A predetermined image can be displayed on the display region 19 by controlling emission luminances of the sub-pixels 2R, 2G and 2B.

Hereinafter, the process S3 of forming the light emitting layers 23R, 23G and 23B through “coating vapor deposition” will be described.

### Embodiment 1

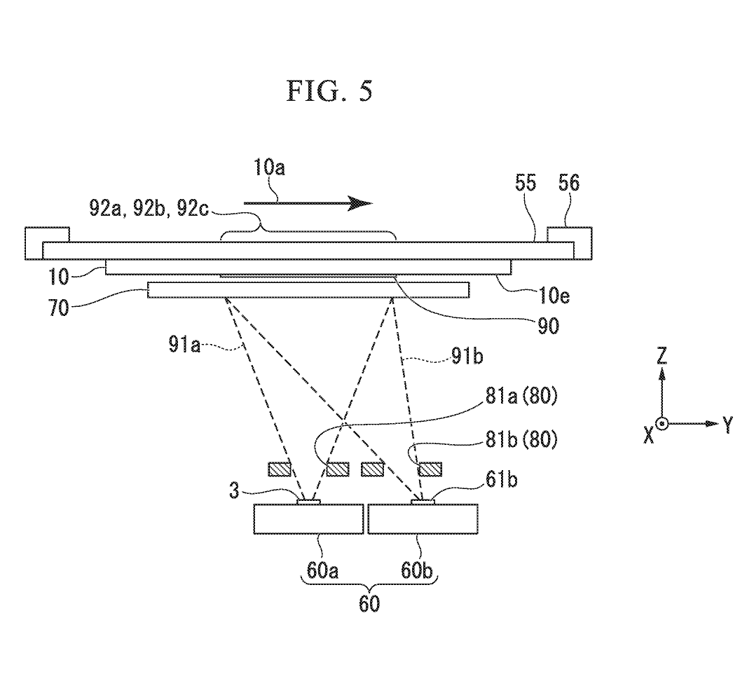

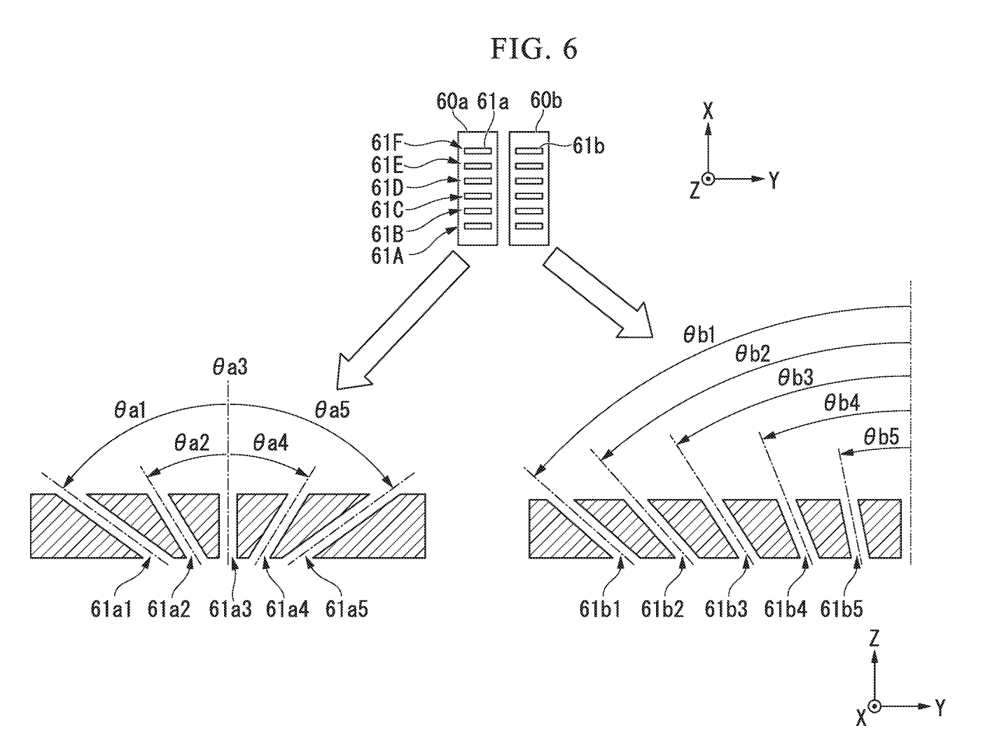

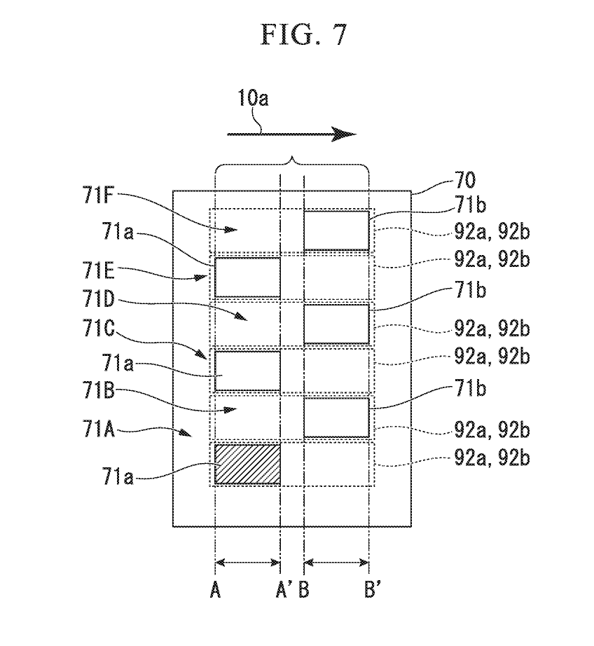

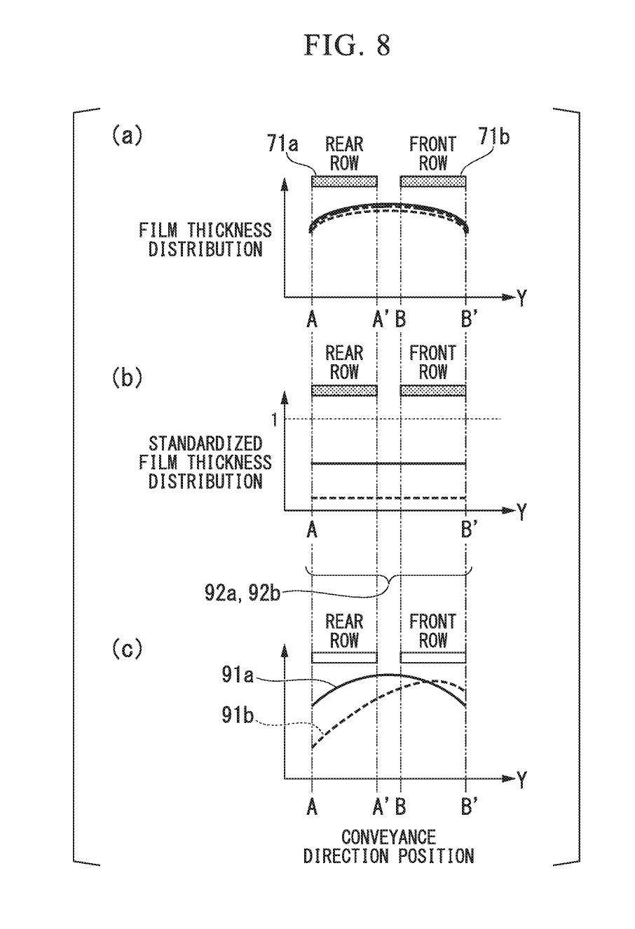

FIG. 5 is a front cross-sectional view along a surface parallel to a moving direction 10a of the substrate 10 illustrating an aspect in which a coat 90 is formed on a substrate 10, showing a view along a surface passing through the vapor deposition source opening perpendicular to the running direction of the substrate of the vapor deposition device according to the embodiment, FIG. 6 is a cross-sectional view showing the vapor deposition source opening of the vapor deposition device shown in FIG. 5, FIG. 7 is a plan view showing the vapor deposition mask opening of the vapor deposition device shown in FIG. 5, and FIG. 8 is graphs showing setting conditions of the vapor deposition source opening of the vapor deposition device shown in FIG. 6, FIG. 8(a) showing a graph of a film thickness distribution in the substrate conveyance direction due to the vapor deposition source opening of the embodiment, FIG. 8(b) showing a graph of a standardized film thickness distribution in the substrate conveyance direction due to the vapor deposition source opening of the embodiment, and FIG. 8(c) showing a graph of a standardized film thickness distribution in a substrate conveyance direction by a vapor deposition source opening in the related art.

The vapor deposition device according to the embodiment is used in a scanning type vapor deposition (scanning vapor deposition) of performing vapor deposition while relatively moving and scanning the substrate with respect to the mask unit and a vapor deposition source 60 using a vapor deposition mask having a size smaller than the film deposition substrate (the substrate).

Further, in the embodiment, the scanning direction and a direction (a first direction) parallel to the scanning direction are referred to as a Y direction (a Y-axis direction), and a direction (a second direction) perpendicular to the scanning direction is referred to as an X direction (an X-axis direction).

The vapor deposition device according to the embodiment includes a vacuum chamber (a film forming chamber), a substrate holder serving as a substrate holding member configured to hold the film deposition substrate 10, a substrate moving mechanism (a moving mechanism) configured to move the film deposition substrate 10, a vapor deposition unit including the vapor deposition source 60, an alignment observation means such as an image sensor or the like, a control circuit, and so on.

The vapor deposition unit is constituted by the vapor deposition source 60 and a vapor deposition mask 70. The substrate 10 relatively moves with respect to the vapor deposition mask 70 toward a side opposite to the vapor deposition source 60 along an arrow 10a at a constant speed. For the convenience of the following description, an XYZ orthogonal coordinate system in which a horizontal direction axis parallel to the moving direction (the first direction) 10a of the substrate 10 is a Y-axis, a substrate in-plane direction axis perpendicular to the Y-axis is an X-axis, and a direction normal to the substrate axis perpendicular to the X-axis and the Y-axis is a Z axis is set. For the convenience of description, a side of an arrow in the Z-axis direction is referred to as “an upper side.”

The vapor deposition source 60 includes a first vapor deposition source 60a and a second vapor deposition source 60b. The first vapor deposition source 60a and the second vapor deposition source 60b include a plurality of first vapor deposition source openings 61a and a plurality of second vapor deposition source openings 61b on upper surfaces thereof (i.e., surfaces facing the vapor deposition mask 70), respectively. The plurality of first vapor deposition source openings 61a and the plurality of second vapor deposition source openings 61b are disposed at different positions in the Y-axis direction and disposed at a constant pitch along a straight line parallel to the X-axis direction. The plurality of first vapor deposition source openings 61a and the plurality of second vapor deposition source openings 61b are disposed at the same position in the X-axis direction, and as shown in FIG. 8(c), a row 61A, a row 61B, a row 61C, a row 61D, a row 61E and a row 61F in the Y direction are formed. The vapor deposition source openings 61a and 61b have a nozzle shape opening upward along the Z-axis.

The first vapor deposition source openings 61a and the second vapor deposition source openings 61b emit vapor of the first material that is a material of the light emitting layer (i.e., first vapor deposition particles 91a) and vapor of a second material (i.e., second vapor deposition particles 91b) toward the vapor deposition mask 70. For example, vapor (the first vapor deposition particles 91a) of the host that constitutes the light emitting layer can be discharged from the first vapor deposition source openings 61a of the first vapor deposition source 60a, and vapor (the second vapor deposition particles 91b) of the dopant that constitutes the light emitting layer can be discharged from the second vapor deposition source openings 61b of the second vapor deposition source 60b.

The vapor deposition mask 70 is a plate-shaped member having a main surface (a surface having a largest area) that is parallel to an XY plane, a plurality of mask openings 71a in the X-axis direction are formed intermittently at different positions in the X-axis direction, and a plurality of mask openings 71b alternating with the plurality of mask openings 71a are formed intermittently at different positions in the X-axis direction. The mask openings 71a and 71b are through-holes passing through the vapor deposition mask 70 in the Z-axis direction.

The plurality of mask openings 71a are formed at the same position in the X direction, and the plurality of mask openings 71b are formed at the same position in the X direction. The plurality of mask openings 71a and the mask openings 71b are disposed at different positions in the Y direction, the plurality of mask openings 71a constitute a rear row, and the plurality of mask openings 71b constitute a front row. As shown in FIG. 7, the mask openings 71a are disposed at positions of a row 71A, a row 71C and a row 71E in the Y direction, and the mask openings 71b are disposed at positions of a row 71B, a row 71D and a row 71F.

In the plurality of first vapor deposition source openings 61a, the plurality of second vapor deposition source openings 61b, and the plurality of mask openings 71a and 71b, during vapor deposition processing, the row 61A of the vapor deposition source openings 61a and 61b and the row 71A of the mask openings 71a in the Y direction are set to overlap each other when seen in a plan view. Similarly, the row 61B of the vapor deposition source openings 61a and 61b and the row 71B of the mask openings 71b in the Y direction are set to overlap each other when seen in a plan view, the row 61C of the vapor deposition source openings 61a and 61b and the row 71C of the mask openings 71a in the Y direction are set to overlap each other when seen in a plan view, the row 61D of the vapor deposition source openings 61a and 61b and the row 71D of the mask openings 71b in the Y direction are set to overlap each other when seen in a plan view, the row 61E of the vapor deposition source openings 61a and 61b and the row 71E of the mask openings 71a in the Y direction are set to overlap each other when seen in a plan view, and the row 61F of the vapor deposition source openings 61a and 61b and the row 71F of the mask openings 71b in the Y direction are set to overlap each other when seen in a plan view.

While an opening shape of both of the mask openings 71a and 71b is a slit shape parallel to the Y-axis corresponding to a pixel pitch as shown in the row 71A of FIG. 7 in the embodiment, the present invention is not limited thereto and, for example, may be a slot shape. In addition, in FIG. 7, the slit shape corresponding to the pixel pitch of the mask openings 71a and 71b in a row other than the row 71A is not shown. Shapes and dimensions of all the mask openings may be the same or different from each other.

The X-axis direction pitch of the mask openings may be constant or variable. Further, the Y direction region of the mask openings 71a is shown by AA′ and the Y direction region of the mask openings 71b is shown by BB′.

Further, in the embodiment of the present invention, as shown in FIG. 5, a configuration in which a limit plate unit 80 configured to limit a direction in which the first and second vapor deposition particles 91a and 91b are discharged is installed over the vapor deposition source 60 may be provided. In this case, the vapor deposition unit is constituted by the vapor deposition source 60, the vapor deposition mask 70, and the limit plate unit 80 disposed therebetween.

Here, through-holes (limiting apertures) 81a and 81b that are limiting apertures configured to restrict a direction in which the discharged vapor deposition particles 91a and 91b fly to the vicinity in the Z-axis direction with respect to the plurality of first vapor deposition source openings 61a and the plurality of second vapor deposition source openings 61b in the rows 61A to 61F are formed in the limit plate unit 80 at corresponding positions. The directivity is restricted such that the vapor deposition particles 91a and 91b of which the directivity is restricted by the through-holes 81a and 81b reach a first region 92a and a second region 92b on the substrate 10. Here, since the vapor deposition particles pass through only an arbitrary region due to disposing the limit plate, the vapor deposition particles adhere to only arbitrary regions, and specifically, for example, the vapor deposition particles discharged from a vapor deposition source opening 61A are attached to only a mask opening 71A not a mask opening 71B or 71C.

The plurality of vapor deposition source openings 61a and 61b and the vapor deposition mask 70 are separated from each other in the Z-axis direction. Relative positions of the vapor deposition sources 61a and 61b and the vapor deposition mask 70 are preferably substantially constant during at least a period of performing the “coating vapor deposition.”

The substrate 10 is held by a holding device 55. For example, an electrostatic chuck configured to hold a surface opposite to a surface to be vapor-deposited 10e of the substrate 10 using an electrostatic force may be used as the holding device 55. Accordingly, the substrate 10 can be held in a state in which substantially no deformation due to the weight of the substrate 10 occurs. However, the holding device 55 configured to hold the substrate 10 is not limited to an electrostatic chuck and may be another device.

The substrate 10 held by the holding device 55 is scanned (moved) in the moving direction 10a parallel to the Y-axis at a constant speed in a state in which the side opposite to the vapor deposition source 60 with respect to the vapor deposition mask 70 is separated from the vapor deposition mask 70 by a certain interval by a moving mechanism 56. Movement of the substrate 10 may be reciprocal movement or may be single direction movement in any one direction. A configuration of the moving mechanism 56 is not particularly limited. For example, a known conveyance driving mechanism such as a feed screw mechanism, a linear motor, or the like, configured to rotate a feed screw using a motor may be used. A scanning speed may not be constant and may be varied correspondingly to, for example, a vapor deposition rate.

The vapor deposition unit, the substrate 10, the holding device 55 configured to hold the substrate 10, and the moving mechanism 56 configured to move the substrate 10 are accommodated in a vacuum chamber. The vacuum chamber is a sealed container, and an internal space thereof is reduced in pressure and maintained in a predetermined low pressure state.

In the row 61A, both the first vapor deposition particles 91a discharged from the first vapor deposition source openings 61a and the second vapor deposition particles 91b discharged from the second vapor deposition source openings 61b pass through the mask openings 71a that is the rear row of the row 71A in the vapor deposition mask 70.

In the row 61B, either the first vapor deposition particles 91a discharged from the first vapor deposition source openings 61a or the second vapor deposition particles 91b discharged from the second vapor deposition source openings 61b pass through the mask openings 71b that is the front row of the row 71B in the vapor deposition mask 70.

In the row 61C, either the first vapor deposition particles 91a discharged from the first vapor deposition source openings 61a or the second vapor deposition particles 91b discharged from the second vapor deposition source openings 61b pass through the mask openings 71a that is the rear row of the row 71C in the vapor deposition mask 70.

In the row 61D, either the first vapor deposition particles 91a discharged from the first vapor deposition source openings 61a or the second vapor deposition particles 91b discharged from the second vapor deposition source openings 61b pass through the mask openings 71b that is the front row of the row 71D in the vapor deposition mask 70.

In the row 61E, either first vapor deposition particles 91a discharged from the first vapor deposition source openings 61a or the second vapor deposition particles 91b discharged from the second vapor deposition source openings 61b pass through the mask openings 71a that is the rear row of the row 71E in the vapor deposition mask 70.

In the row 61F, either the first vapor deposition particles 91a discharged from the first vapor deposition source openings 61a or the second vapor deposition particles 91b discharged from the second vapor deposition source openings 61b pass through the mask openings 71b that is the front row of the row 71F in the vapor deposition mask 70.

The first and second vapor deposition particles 91a and 91b passing through the mask openings 71a or the mask openings 71b adhere to the surface to be vapor-deposited 10e of the substrate 10 (i.e., the surface on the side facing the vapor deposition mask 70 of the substrate 10) that runs in the Y-axis direction to form the coat 90 in which the first and second vapor deposition particles 91a and 91b are mixed. The coat 90 has a stripe shape corresponding to the pixel pitch extending in the Y-axis direction corresponding to the mask openings 71a or the mask openings 71b.

As described above, when the material of the first vapor deposition particles 91a is the host and the material of the second vapor deposition particles 91b is the dopant, the coat 90 in which the dopant is dispersed and contained in the host can be formed.

Since at least one of the materials of the first vapor deposition particles 91a and the second vapor deposition particles 91b is changed according to colors of red, green and blue when performing vapor deposition (“coating vapor deposition”) three times, the stripe-shaped coat 90 (i.e., the light emitting layers 23R, 23G and 23B) corresponding to the colors of red, green and blue can be formed on the surface to be vapor-deposited 10e of the substrate 10.

In the embodiment, the first and second limit nozzles are installed in the first vapor deposition source openings 61a and the second vapor deposition source openings 61b, and a distribution in which the film thickness distribution of the host/dopant is uniform in the conveyance direction 10a is made possible.

In the embodiment, when a region on the substrate 10 to which the first vapor deposition particles 91a having directivity restricted by the limit plate unit 80 adhere is the first region 92a and a region on the substrate 10 to which the second vapor deposition particles 91b having directivity restricted by the limit plate unit 80 adhere is the second region 92b, a position of the first region 92a in the Y-axis direction substantially coincides with a position of the second region 92b in the Y-axis direction.

In other words, relative positions (distances, angles, and so on) between the first and second vapor deposition source openings 61a and 61b, the limit plate unit 80 and the substrate 10 are set such that the first region 92a and the second region 92b substantially coincide with each other. Then, the mask openings 71a and 71b are formed in the region on the vapor deposition mask 70 in which portions of the mask openings 71a and 71b correspond to the region in which the first and second vapor deposition particles 91a and 91b overlap. Preferably, all of the mask openings 71a and 71b are formed in the region on the vapor deposition mask 70 corresponding to the region in which the first and second vapor deposition source openings 61a and 61b overlap. FIG. 7 shows a relationship between the mask openings 71a and 71b, the first vapor deposition source openings 61a, and the first region 92a and the second region 92b that are the regions on the substrate 10 corresponding to the second vapor deposition source openings 61b at the position of the vapor deposition mask 70.

As shown in FIG. 8(c), the first and second vapor deposition particles 91a and 91b when there is no limit nozzle are discharged from the first and second vapor deposition source openings 61a and 61b with a certain a spread (directivity) in the X-axis direction and the Y-axis direction as they are when there are no limit nozzles. In this case, both the first vapor deposition source openings 61a and the second vapor deposition source openings 61b open in a direction parallel to the Z-axis.

The number of first vapor deposition particles 91a discharged from the first vapor deposition source openings 61a is largest at a center of the first vapor deposition source openings 61a in an opening direction (in the example, in the Z-axis direction) when there is no limit nozzle, and gradually reduces as an angle (an emission angle) with respect to the opening direction increases. That is, the first vapor deposition particles 91a have a distribution in which a peak is provided at a position immediately above the first vapor deposition source openings 61a and decreased forward and rearward in the Y direction (the conveyance direction).

The number of second vapor deposition particles 91b discharged from the second vapor deposition source openings 61b is largest at a center of the second vapor deposition source openings 61b in the opening direction (in the example, the Z-axis direction) when there is no limit nozzle, and gradually reduces as an angle (an emission angle) with respect to the opening direction increases. That is, the second vapor deposition particles 91b have a distribution in which a peak is provided at a position immediately above the second vapor deposition source openings 61b and decreased forward and rearward in the Y direction (the conveyance direction).

In this way, the distribution of the second vapor deposition particles 91b is in a state reversed in the Y direction (the conveyance direction) and has a difference in magnitude larger than in the distribution of the first vapor deposition particles 91a.

In the embodiment, as shown in FIG. 6, first limit nozzles 61a1, 61a2, 61a3, 61a4 and 61a5 separated from each other at five places in the Y direction 10a are installed in the first vapor deposition source openings 61a and second limit nozzles 61b1, 61b2, 61b3, 61b4 and 61b5 separated from each other at five places in the Y direction 10a are installed in the second vapor deposition source openings 61b correspondingly to correct a deviation of the distribution in the first and second vapor deposition particles 91a and 91b.

In the second vapor deposition source openings 61b, as shown in FIG. 8(c), a state in which the number of second vapor deposition particles 91b discharged from the second vapor deposition source openings 61b when there is no limit nozzle is increased at a front side in the conveyance direction other than a center between A-B′ in the Y direction 10a is corrected to obtain a balance in distribution, and as shown in FIG. 8(a), becomes a shape in which a distribution of the number of discharged second vapor deposition particles 91b is set such that the distribution between A-B′ in the Y direction 10a is as uniform a profile as possible. That is, the second vapor deposition source openings 61b are set such that the distribution of the number of the second vapor deposition particles 91b standardized with the distribution of the number of the first vapor deposition particles 91a between A-B′ in the Y direction 10a is uniformized between A-B′ as shown in FIG. 8(b).

Specifically, as shown in FIG. 6, an opening cross-sectional inclination angle θb5 of the second limit nozzle 61b5 disposed at the foremost side in the conveyance direction is set to be smallest, and the opening cross-sectional inclination angle is set to be increased toward the rear side in the conveyance direction. That is, the opening cross-sectional inclination angles are set to satisfy θb5<θb4<θb3<θb2<θb3.

In the first vapor deposition source openings 61a, as shown in FIG. 8(c), a state in which the number of the first vapor deposition particles 91a discharged from the first vapor deposition source openings 61a when there is no limit nozzle is increased at a center between A-B′ in the Y direction 10a is corrected, and as shown in FIG. 8(a), becomes a shape in which the distribution of the number of the discharged first vapor deposition particles 91a is set such that a difference in distribution between A-B′ in the Y direction 10a is reduced. Specifically, as shown in FIG. 6, an opening cross-sectional inclination angle θa3 of the first limit nozzle 61a3 of the center is set to be smallest, the opening cross-sectional inclination angles θa2 and θa4 of the first limit nozzles 61a2 and 61a4 disposed at both sides thereof are set to be larger than θa3, and further, the opening cross-sectional inclination angles θa1 and θa5 of the first limit nozzles 61a1 and 61a5 disposed outside both sides thereof are set to be larger than θa2 and θa4.

In the embodiment, the first region 92a to which the first vapor deposition particles 91a adhere and the second region 92b to which the second vapor deposition particles 91b adhere substantially coincide with each other, and further, as shown in FIGS. 8(a) and 8(b), the coat 90 in which a mixing ratio of the first vapor deposition particles 91a and the second vapor deposition particles 91b is constant in the conveyance direction 10a can be formed.

Accordingly, regardless of the positions of the mask openings 71a and 71b in the conveyance direction 10a, a film thickness distribution and a number of particles ratio of the first vapor deposition particles 91a and the second vapor deposition particles 91b are constant, and the coat 90 in which the mixing ratio thereof is constant can be easily formed. Accordingly, the host/dopant ratio is constant regardless of the position in the conveyance direction. Accordingly, when the light emitting layers 23R, 23G and 23B are formed in the embodiment, since an organic EL element having emission properties and current properties that are improved and stabilized can be formed, a large organic EL display device having good reliability and display quality can be obtained.

In the embodiment, in a state in which the directivity of the first and second vapor deposition particles 91a and 91b toward the substrate 10 in the Y-axis direction is restricted by setting shapes for the limit nozzles 61a1 to 61b6 and thus the first region 92a on the substrate 10 to which the first vapor deposition particles 91a adhere substantially coincides with the second region 92b on the substrate 10 to which the second vapor deposition particles 91b are attached when there is no vapor deposition mask 70, it is important to realize uniformization of the number of particles in these regions. Accordingly, even when the mask openings 71a and 71b are disposed in the conveyance direction 10a as the front row/the rear row, regardless of the positions of the mask openings 71a and 71b in the conveyance direction 10a, the host/dopant ratio can be constant. However, the present invention is not limited thereto.

While only the opening cross-sectional inclination angle of the limit nozzles 61a1 to 61b6 has been described as being set in the embodiment, there is no limitation thereto and the configuration is not limited as long as the directivity of the first and second vapor deposition particles 91a and 91b toward the substrate 10 in the Y-axis direction can be controlled and uniformization of the number of particles in the first and second regions 92a and 92b can be realized.

### Embodiment 2

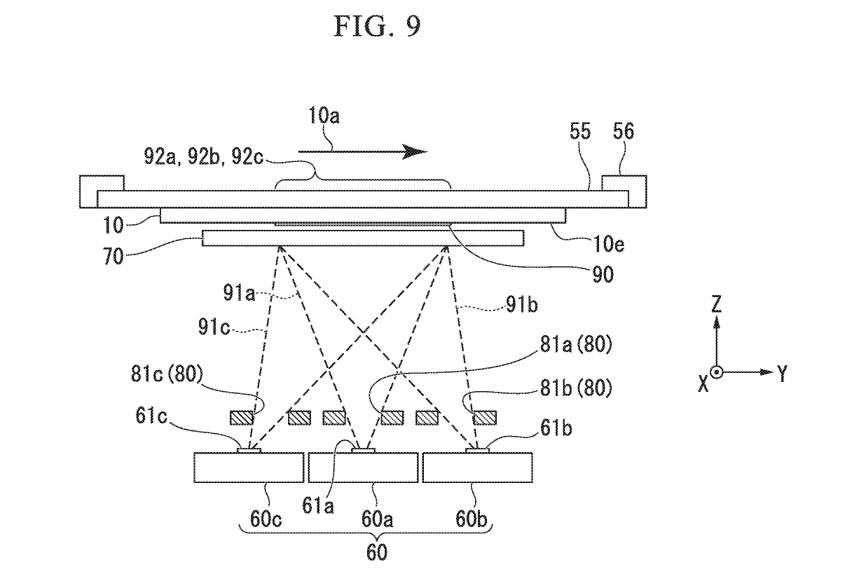

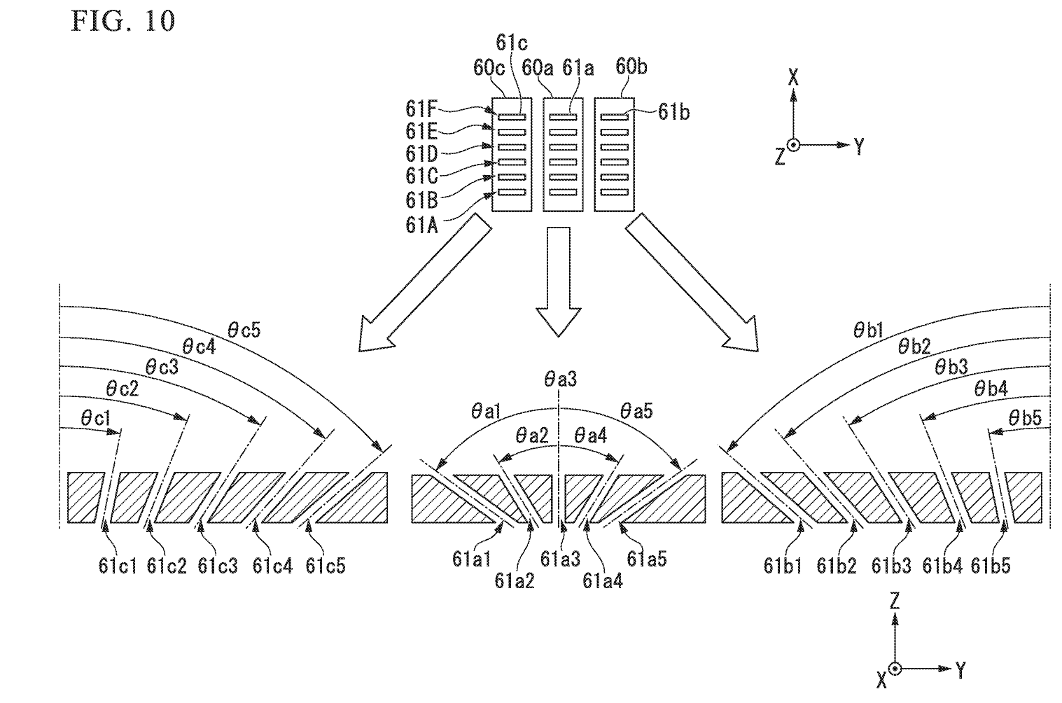

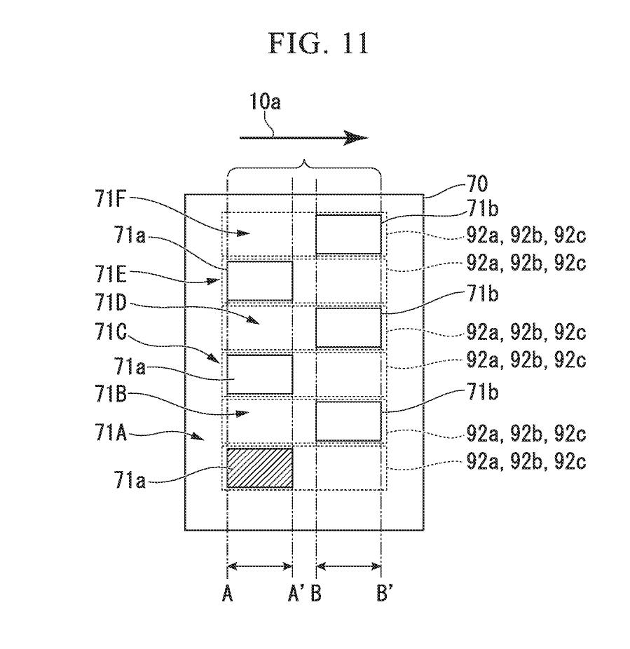

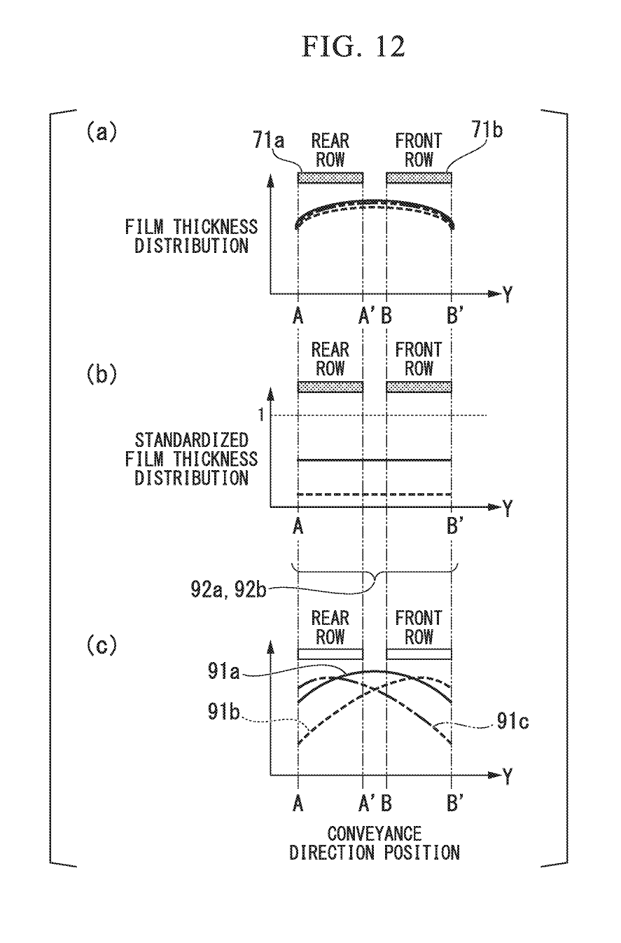

FIG. 9 is a front cross-sectional view along a surface parallel to a moving direction 10a of a substrate 10 showing an aspect in which a coat 90 is formed on the substrate 10, as a view along a surface passing through a vapor deposition source opening perpendicular to a running direction of a substrate of a vapor deposition device according to a second embodiment of the present invention, FIG. 10 is a cross-sectional view showing the vapor deposition source opening of the vapor deposition device shown in FIG. 9, FIG. 11 is a plan view showing a vapor deposition mask opening of the vapor deposition device shown in FIG. 9, and FIG. 12 is a graph showing setting conditions of the vapor deposition source opening of the vapor deposition device shown in FIG. 10, FIG. 12(a) showing a graph of a film thickness distribution in a substrate conveyance direction due to the vapor deposition source opening of the embodiment, FIG. 12(b) showing a graph of a standardized film thickness distribution in the substrate conveyance direction due to the vapor deposition source opening of the embodiment, and FIG. 12(c) showing a graph showing a standardized film thickness distribution in a substrate conveyance direction by a vapor deposition source opening in the related art.

The vapor deposition device according to the embodiment uses a vapor deposition mask having a size smaller than the film deposition substrate (the substrate), vapor deposition is performed while relatively moving and scanning the substrate with respect to the mask unit and the vapor deposition source 60, and vapor deposition (scanning vapor deposition) of a scanning type is used.

Further, in the embodiment, the scanning direction and the direction (the first direction) parallel to the scanning direction are referred to as the Y direction (the Y-axis direction), and the direction (the second direction) perpendicular to the scanning direction is referred to as the X direction (the X-axis direction).

The vapor deposition device according to the embodiment includes a vacuum chamber (a film forming chamber), a substrate holder serving as a substrate holding member configured to hold the film deposition substrate 10, a substrate moving mechanism (a moving mechanism) configured to move the film deposition substrate 10, a vapor deposition unit including the vapor deposition source 60, an alignment observation means such as an image sensor or the like, a control circuit, and so on.

The vapor deposition unit is constituted by the vapor deposition source 60 and the vapor deposition mask 70. The substrate 10 relatively moves with respect to the vapor deposition mask 70 toward the side opposite to the vapor deposition source 60 along the arrow 10a at a constant speed. For the convenience of the following description, an XYZ orthogonal coordinate system in which a horizontal direction axis parallel to the moving direction (the first direction) 10a of the substrate 10 is a Y-axis, a substrate in-plane direction axis perpendicular to the Y-axis is an X-axis, and a direction normal to the substrate axis perpendicular to the X-axis and the Y-axis is a Z-axis is set. For the convenience of description, a side of an arrow in the Z-axis direction is referred to as “an upper side.”

The vapor deposition source 60 includes the first vapor deposition source 60a, the second vapor deposition source 60b and the third vapor deposition source 60c.

The first vapor deposition source 60a, the second vapor deposition source 60b and the third vapor deposition source 60c include a plurality of first vapor deposition source openings 61a, a plurality of second vapor deposition source openings 61b and a plurality of third vapor deposition source openings 61c on upper surfaces thereof (i.e., surfaces facing the vapor deposition mask 70), respectively. The plurality of first vapor deposition source openings 61a, the plurality of second vapor deposition source openings 61b and the plurality of third vapor deposition source openings 61c are disposed at different positions in the Y-axis direction and disposed at a constant pitch along a straight line parallel to the X-axis direction. The plurality of first vapor deposition source openings 61a, the plurality of second vapor deposition source openings 61b and the plurality of third vapor deposition source openings 61c are disposed at the same position in the X-axis direction, and as shown in FIG. 10, form the row 61A, the row 61B, the row 61C, the row 61D, the row 61E and the row 61F in the Y direction. The vapor deposition source openings 61a, 61b and 61c having a nozzle shape opening upward along the Z-axis.

The first vapor deposition source openings 61a, the second vapor deposition source openings 61b and the third vapor deposition source openings 61c discharge vapor of the first material (i.e., the first vapor deposition particles 91a), vapor of the second material (i.e., the second vapor deposition particles 91b), and vapor of the third material (i.e., third vapor deposition particles 91c), which are the material of the light emitting layer, toward the vapor deposition mask 70, respectively. For example, the vapor of the host (the first vapor deposition particles 91a) that constitutes the light emitting layer can be discharged from the first vapor deposition source openings 61a of the first vapor deposition source 60a, the vapor of the assist (the second vapor deposition particles 91b) that constitutes the light emitting layer can be discharged from the second vapor deposition source openings 61b of the second vapor deposition source 60b, and the vapor of the dopant (the third vapor deposition particles 91c) that constitutes the light emitting layer can be discharged from the third vapor deposition source openings 61c of the third vapor deposition source 60c.

The vapor deposition mask 70 is a plate-shaped member having a main surface (a surface having a largest area) parallel to an XY plane, the plurality of mask openings 71a are formed intermittently in the X-axis direction at different positions in the X-axis direction, and the plurality of mask openings 71b alternating with the plurality of mask openings 71a are formed intermittently at different positions in the X-axis direction. The mask openings 71a and 71b are through-holes passing through the vapor deposition mask 70 in the Z-axis direction.

The plurality of mask openings 71a are formed to be disposed at the same position in the X direction, and the plurality of mask openings 71b are formed to be disposed at the same position in the X direction. The plurality of mask openings 71a and the mask openings 71b are disposed at different positions in the Y direction, the plurality of mask openings 71a constitute the rear row, and the plurality of mask openings 71b constitute the front row. As shown in FIG. 11, the mask openings 71a are disposed at positions of the row 71A, the row 71C and the row 71E in the Y direction, and the mask openings 71b are disposed at positions of the row 71B, the row 71D and the row 71F.

In the plurality of first vapor deposition source openings 61a, the plurality of second vapor deposition source openings 61b and the plurality of third vapor deposition source openings 61c, and the plurality of mask openings 71a and 71b, during vapor deposition processing, the row 61A of the vapor deposition source openings 61a, 61b and 61c and the row 71A of the mask openings 71a in the Y direction are set to overlap each other when seen in a plan view. Similarly, the row 61B of the vapor deposition source openings 61a, 61b and 61c and the row 71B of the mask openings 71b in the Y direction are set to overlap each other when seen in a plan view, the row 61C of the vapor deposition source openings 61a, 61b and 61c and the row 71C of the mask openings 71a in the Y direction are set to overlap each other when seen in a plan view, the row 61D of the vapor deposition source openings 61a, 61b and 61c and the row 71D of the mask openings 71b in the Y direction are set to overlap each other when seen in a plan view, the row 61E of the vapor deposition source openings 61a, 61b and 61c and the row 71E of the mask openings 71a in the Y direction are set to overlap each other when seen in a plan view, and the row 61F of the vapor deposition source openings 61a, 61b and 61c and the row 71F of the mask openings 71b in the Y direction are set to overlap each other when seen in a plan view.

In the embodiment, while both of opening shapes of the mask openings 71a and 71b have a slit shape parallel to the Y-axis corresponding to the pixel pitch as shown by the row 71A in FIG. 11, the present invention is not limited thereto and, for example, they may have a slot shape. In addition, in FIG. 11, illustration of the slit shape corresponding to the pixel pitch of the mask openings 71a and 71b in rows other than the row 71A is omitted. The shapes and the dimensions of all of the mask openings may be the same or may be different from each other. The pitch of the mask openings in the X-axis direction may be constant or may be variable. Further, the Y direction region of the mask openings 71a is shown by AA′ and the Y direction region of the mask openings 71b is shown by BB′.

Further, in the embodiment of the present invention, as shown in FIG. 9, a configuration in which the limit plate unit 80 configured to restrict the direction in which the first to third vapor deposition particles 91a to 91c are discharged is installed over the vapor deposition source 60 can be provided. In this case, the vapor deposition unit is constituted by the vapor deposition source 60, the vapor deposition mask 70, and the limit plate unit 80 disposed therebetween.

Here, through-holes (limiting apertures) 81a, 81b and 81c that are limiting apertures configured to restrict the directionality in which the discharged vapor deposition particles 91a to 91c fly to the vicinity in the Z-axis direction with respect to the plurality of first vapor deposition source openings 61a, the plurality of second vapor deposition source openings 61b and the plurality of third vapor deposition source openings 61c in the rows 61A to 61F are formed in the limit plate unit 80. The directivity is restricted such that the vapor deposition particles 91a to 91c of which the directivity is restricted by the through-holes 81a, 81b and 81c can reach the first region 92a, the second region 92b and a third region 92c on the substrate 10. Here, the vapor deposition particles pass through only an arbitrary region due to disposing the limit plate and do not adhere to a region other than the arbitrary region, and specifically, for example, the vapor deposition particles discharged from the vapor deposition source opening 61A are attached to the mask opening 71A not the mask opening 71B or 71C.

The plurality of vapor deposition source openings 61a, 61b and 61c and the vapor deposition mask 70 are separated from each other in the Z-axis direction. Relative positions between the vapor deposition sources 61a, 61b and 61c and the vapor deposition mask 70 may be substantially constant during a period of performing at least “coating vapor deposition.”

The substrate 10 is held by the holding device 55. For example, an electrostatic chuck configured to hold a surface opposite to the surface to be vapor-deposited 10e of the substrate 10 with an electrostatic force may be used as the holding device 55. Accordingly, the substrate 10 can be held in a state in which there is substantially no bending due to the weight of the substrate 10. However, the holding device 55 configured to hold the substrate 10 is not limited to an electrostatic chuck and may be the other device.

The substrate 10 held by the holding device 55 is scanned (moved) at a constant speed in the moving direction 10a parallel to the Y-axis in a state in which the side opposite to the vapor deposition source 60 with respect to the vapor deposition mask 70 is separated from the vapor deposition mask 70 by a constant interval by the moving mechanism 56. Movement of the substrate 10 may be reciprocal movement or may be a single direction movement in any one direction. A configuration of the moving mechanism 56 is not particularly limited. For example, a known conveyance driving mechanism such as a feed screw mechanism, a linear motor, or the like, configured to rotate a feed screw using a motor may be used. A scanning speed may not be constant, and for example, may be varied according to the vapor deposition rate.

The vapor deposition unit, the substrate 10, the holding device 55 configured to hold the substrate 10, and the moving mechanism 56 configured to move the substrate 10 are accommodated in a vacuum chamber. The vacuum chamber is a sealed container, and an internal space thereof is reduced in pressure and maintained in a predetermined low pressure state.

In the row 61A, all of the first vapor deposition particles 91a discharged from the first vapor deposition source openings 61a, the second vapor deposition particles 91b discharged from the second vapor deposition source openings 61b, and the third vapor deposition particles 91c discharged from the third vapor deposition source openings 61c pass through the mask openings 71a that is the rear row of the row 71A in the vapor deposition mask 70.

In the row 61B, all of the first vapor deposition particles 91a discharged from the first vapor deposition source openings 61a, the second vapor deposition particles 91b discharged from the second vapor deposition source openings 61b, and the third vapor deposition particles 91c discharged from the third vapor deposition source openings 61c pass through the mask opening 71b that is the front row of the row 71B in the vapor deposition mask 70.

In the row 61C, all of the first vapor deposition particles 91a discharged from the first vapor deposition source openings 61a, the second vapor deposition particles 91b discharged from the second vapor deposition source openings 61b, and the third vapor deposition particles 91c discharged from the third vapor deposition source openings 61c pass through the mask opening 71a that is the rear row of the row 71C in the vapor deposition mask 70.

In the row 61D, all of the first vapor deposition particles 91a discharged from the first vapor deposition source openings 61a, the second vapor deposition particles 91b discharged from the second vapor deposition source openings 61b, and the third vapor deposition particles 91c discharged from the third vapor deposition source openings 61c pass through the mask opening 71b that is the front row of the row 71D in the vapor deposition mask 70.

In the row 61E, all of the first vapor deposition particles 91a discharged from the first vapor deposition source openings 61a, the second vapor deposition particles 91b discharged from the second vapor deposition source openings 61b, and the third vapor deposition particles 91c discharged from the third vapor deposition source openings 61c pass through the mask opening 71a that is the rear row of the row 71E in the vapor deposition mask 70.

In the row 61F, all of the first vapor deposition particles 91a discharged from the first vapor deposition source openings 61a, the second vapor deposition particles 91b discharged from the second vapor deposition source openings 61b, and the third vapor deposition particles 91c discharged from the third vapor deposition source openings 61c pass through the mask opening 71b that is the front row of the row 71F in the vapor deposition mask 70.

The first to third vapor deposition particles 91a, 91b and 91c passing through the mask openings 71a or the mask openings 71b adhere to the surface to be vapor-deposited 10e (i.e., the surface facing the vapor deposition mask 70 of the substrate 10) of the substrate 10 that runs in the Y-axis direction to form the coat 90 in which the first to third vapor deposition particles 91a, 91b and 91c are mixed. The coat 90 has a stripe shape corresponding to the pixel pitch extending in the Y-axis direction corresponding to the mask openings 71a or the mask openings 71b.

As described above, when the material of the first vapor deposition particles 91a is the host, the material of the second vapor deposition particles 91b is the assist and the material of the third vapor deposition particles 91c is the dopant, the coat 90 in which the assist and the dopant are dispersed and contained in the host can be formed.

Since at least one of the materials of the first vapor deposition particles 91a, the second vapor deposition particles 91b and the third vapor deposition particles 91c is changed according to the colors of red, green and blue when performing vapor deposition (“coating vapor deposition”) three times, the stripe-shaped coat 90 (i.e., the light emitting layers 23R, 23G and 23B) corresponding to the colors of red, green and blue can be formed on the surface to be vapor-deposited 10e of the substrate 10.

In the embodiment, the first to third limit nozzles are installed in the first vapor deposition source openings 61a, the second vapor deposition source openings 61b and the third vapor deposition source openings 61c, respectively, and the film thickness distribution of the host/assist/dopant can be provided in the same shape in the conveyance direction 10a.

In the embodiment, when the region on the substrate 10 to which the first vapor deposition particles 91a having directivity restricted by the limit plate unit 80 adhere is the first region 92a, the region on the substrate 10 to which the second vapor deposition particles 91b having directivity restricted by the limit plate unit 80 adhere is the second region 92b, and the region in the substrate 10 to which the third vapor deposition particles 91c having directivity restricted by the limit plate unit 80 adhere is the third region 92c, the position of the first region 92a in the Y-axis direction, the position of the second region 92b in the Y-axis direction and the position of the third region 92c in the Y-axis direction substantially coincide with each other.

In other words, relative positions (distances/angles, and so on) between the first to third vapor deposition source openings 61a, 61b and 61c and the limit plate unit 80 and the substrate 10 are set such that the first region 92a, the second region 92b and the third region 92c substantially coincide with each other. Then, some of the mask openings 71a and 71b are formed in the region on the vapor deposition mask 70 corresponding to the region in which the first to third vapor deposition particles 91a to 91c overlap. Preferably, all of the mask openings 71a and 71b are formed in the region on the vapor deposition mask 70 corresponding to the region in which the first to third vapor deposition source openings 61a, 61b and 61c overlap. FIG. 11 shows a relationship between the first region 92a, the second region 92b and the third region 92c that are the regions on the substrate 10 corresponding to the mask openings 71a and 71b, the first vapor deposition source openings 61a, the second vapor deposition source openings 61b and the third vapor deposition source openings 61c at the positions in the vapor deposition mask 70.

As shown in FIG. 12(c), the first to third vapor deposition particles 91a, 91b and 91c when there is no limit nozzle are discharged from the first to third vapor deposition source openings 61a, 61b and 61c with a spread (directivity) in the X-axis direction and the Y-axis direction as they are. In this case, the first vapor deposition source openings 61a open in the direction parallel to the Z-axis.

The number of the first vapor deposition particles 91a discharged from the first vapor deposition source openings 61a is largest at the center in the opening direction (in the example, in the Z-axis direction) of the first vapor deposition source openings 61a when there is no limit nozzle, and gradually reduces as an angle (an emission angle) formed with respect to the opening direction increases. That is, the first vapor deposition particles 91a have a distribution in which a peak is provided at a position immediately above the first vapor deposition source openings 61a and decreased forward and rearward in the Y direction (the conveyance direction).

The number of the second vapor deposition particles 91b discharged from the second vapor deposition source openings 61b is largest at the center of the second vapor deposition source openings 61b in the opening direction (in the example, in the Z-axis direction) when there is no limit nozzle, and gradually reduces as an angle (an emission angle) formed with respect to the opening direction increases. That is, the second vapor deposition particles 91b have a distribution in which a peak is provided at a position immediately over the second vapor deposition source openings 61b and decreased forward and rearward in the Y direction (the conveyance direction).

Similarly, the number of the third vapor deposition particles 91c discharged from the third vapor deposition source openings 61c is largest at the center of the third vapor deposition source openings 61c in the opening direction (in the example, in the Z-axis direction) when there is no limit nozzle, and gradually reduces as an angle (an emission angle) formed with respect to the opening direction increases. That is, the third vapor deposition particles 91c has a distribution in which a peak is provided at a position immediately above the third vapor deposition source openings 61c and decreased forward and rearward in the Y direction (the conveyance direction).

In this way, the distribution of the second vapor deposition particles 91b and the distribution of the third vapor deposition particles 91c are in a state reversed in the Y direction (the conveyance direction) and have a difference in magnitude larger than in the distribution of the first vapor deposition particles 91a.

In the embodiment, as shown in FIG. 10, the first limit nozzles 61a1, 61a2, 61a3, 61a4 and 61a5 separated from each other at five places in the Y direction 10a are installed in the first vapor deposition source openings 61a, the second limit nozzles 61b1, 61b2, 61b3, 61b4 and 61b5 separated from each other at five places in the Y direction 10a are installed in the second vapor deposition source openings 61b, and third limit nozzles 61c1, 61c2, 61c3, 61c4 and 61c5 separated from each other at five places in the Y direction 10a are installed in the third vapor deposition source openings 61c correspondingly to correct a deviation of the distribution in the first to third vapor deposition particles 91a, 91b and 91c.

In the second vapor deposition source openings 61b, as shown in FIG. 12(c), a state in which the number of the second vapor deposition particles 91b discharged from the second vapor deposition source openings 61b when there is no limit nozzle is increased at a front side in the conveyance direction other than a center between A-B′ in the Y direction 10a is corrected to obtain a balance in distribution, and as shown in FIG. 12(a), becomes a shape in which a distribution of the number of the discharged second vapor deposition particles 91b is set such that the distribution between A-B′ in the Y direction 10a is as uniform a profile as possible. That is, the second vapor deposition source openings 61b are set such that the distribution of the number of the second vapor deposition particles 91b standardized with the distribution of the number of the first vapor deposition particles 91a between A-B′ in the Y direction 10a is uniformized between A-B′ as shown in FIG. 12(b).

Specifically, as shown in FIG. 10, an opening cross-sectional inclination angle θb5 of the second limit nozzle 61b5 disposed at the foremost side in the conveyance direction is set to be smallest, and the opening cross-sectional inclination angle is set to be increased toward the rear side in the conveyance direction. That is, the opening cross-sectional inclination angles are set to satisfy θb5<θb4<θb3<θb2<θb3.

In the third vapor deposition source openings 61c, as shown in FIG. 12(c), a state in which the number of the third vapor deposition particles 91c discharged from the third vapor deposition source openings 61c when there is no limit nozzle is higher at a rear side in the conveyance direction than at the center between A-B′ in the Y direction 10a is corrected to obtain a balance in distribution, and as shown in FIG. 12(a), becomes a shape in which the distribution of the number of the discharged third vapor deposition particles 91c is set such that a distribution between A-B′ in the Y direction 10a is as uniform a profile as possible. That is, the third vapor deposition source openings 61c are set such that the distribution of the number of the third vapor deposition particles 91c standardized with the distribution of the number of the first vapor deposition particles 91a between A-B′ in the Y direction 10a is uniformized between A-B′ as shown in FIG. 12(b).

Specifically, as shown in FIG. 10, an opening cross-sectional inclination angle θc1 in the third limit nozzle 61c1 disposed at the rearmost side in the conveyance direction is set to be smallest, and the opening cross-sectional inclination angle is set to be increased toward the front side in the conveyance direction. That is, the opening cross-sectional inclination angle is set to be θc1<θc2<θc3<θc4<θc5.

In the first vapor deposition source openings 61a, as shown in FIG. 12(c), a state in which the number of the first vapor deposition particles 91a discharged from the first vapor deposition source openings 61a when there is no limit nozzle is increased at the center between A-B′ in the Y direction 10a is corrected, and as shown in FIG. 12(a), becomes a shape in which the distribution of the number of the discharged first vapor deposition particles 91a is set to reduce a difference in distribution between A-B′ in the Y direction 10a. Specifically, as shown in FIG. 10, the opening cross-sectional inclination angle θa3 in the first limit nozzle 61a3 of the center is set to be smallest, the opening cross-sectional inclination angles θa2 and θa4 in the first limit nozzles 61a2 and 61a4 disposed at both sides thereof are set to be larger than θa3, and further, the opening cross-sectional inclination angles θa1 and θa5 in the first limit nozzles 61a1 and 61a5 disposed outside both sides thereof are set to be larger than θa2 and θa4.

In the embodiment, the first region 92a to which the first vapor deposition particles 91a adhere, the second region 92b to which the second vapor deposition particles 91b adhere, and the third region 92c to which the third vapor deposition particles 91c adhere substantially coincide with each other, and further, as shown in FIGS. 12(a) and 12(b), the coat 90 in which a mixing ratio of the first vapor deposition particles 91a, the second vapor deposition particles 91b and the third vapor deposition particles 91c is constant in the conveyance direction 10a can be formed.

Accordingly, regardless of the positions of the mask openings 71a and 71b in the conveyance direction 10a, the film thickness distribution and the number of particles ratio of the first vapor deposition particles 91a, the second vapor deposition particles 91b and the third vapor deposition particles 91c are kept constant, and thus, the coat 90 in which the mixing ratio thereof is constant can be easily formed. Accordingly, the host/assist/dopant ratio is constant regardless of the position in the conveyance direction. Accordingly, when the light emitting layers 23R, 23G and 23B are formed according to the embodiment, since the organic EL element having emission properties and current properties that are improved and stabilized can be formed, a large organic EL display device having good reliability and display quality can be obtained.

In the embodiment, in a state in which the directivity of the first to third vapor deposition particles 91a, 91b and 91c toward the substrate 10 in the Y-axis direction is restricted by setting the shapes of the limit nozzles 61a1 to 61c6, and thus, the first region 92a on the substrate 10 to which the first vapor deposition particles 91a adhere, the second region 92b on the substrate 10 to which the second vapor deposition particles 91b adhere, and the third region 92c on the substrate 10 to which the third vapor deposition particles 91c adhere when the vapor deposition mask 70 is not provided substantially coincide with each other, it is important to realize uniformization of the number of particles in these regions. Accordingly, even when the mask openings 71a and 71b are disposed in the conveyance direction 10a and the front row/rear row, regardless of the positions of the mask openings 71a and 71b in the conveyance direction 10a, the host/assist/dopant ratio can be constant. However, the present invention is not limited thereto.

In the embodiment, while only the opening shapes of the limit nozzles 61a1 to 61c6 have been described as being set, there is no limitation thereto and the embodiment is not limited as long as the directivity of the first to third vapor deposition particles 91a, 91b and 91c toward the substrate 10 in the Y-axis direction is controlled and uniformization of the number of particles in the first to third regions 92a, 92b and 92c can be realized.

### Embodiment 3

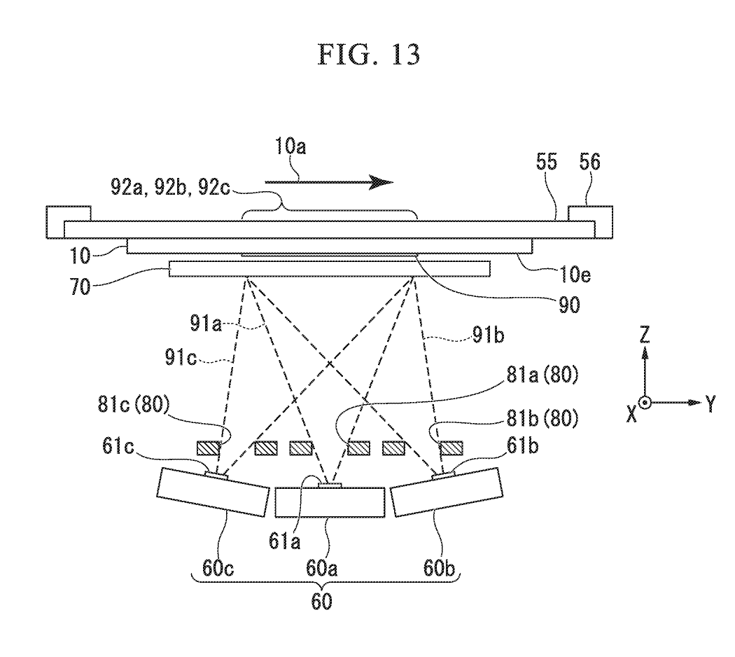

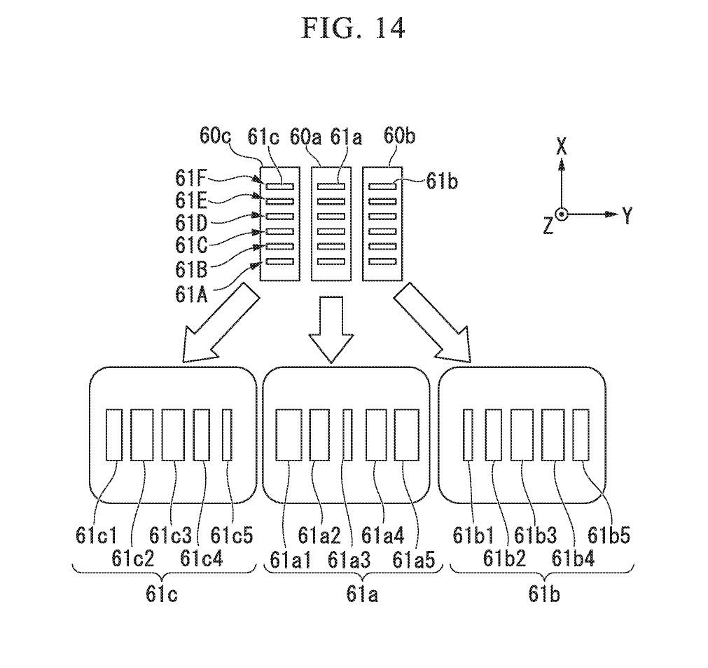

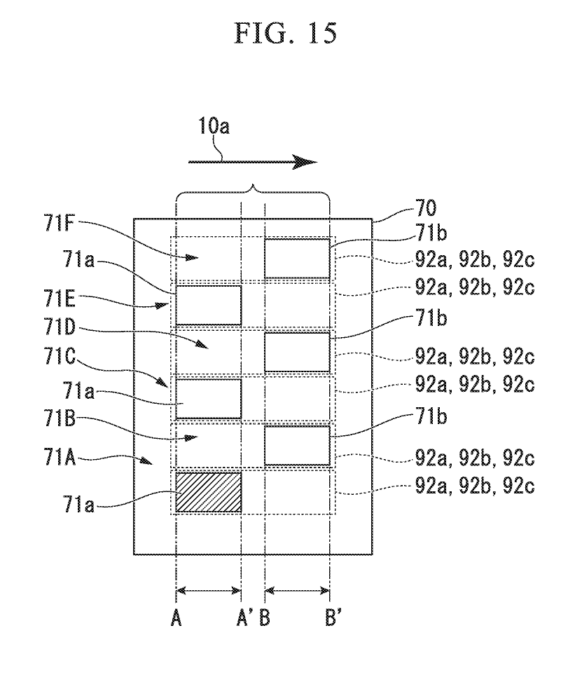

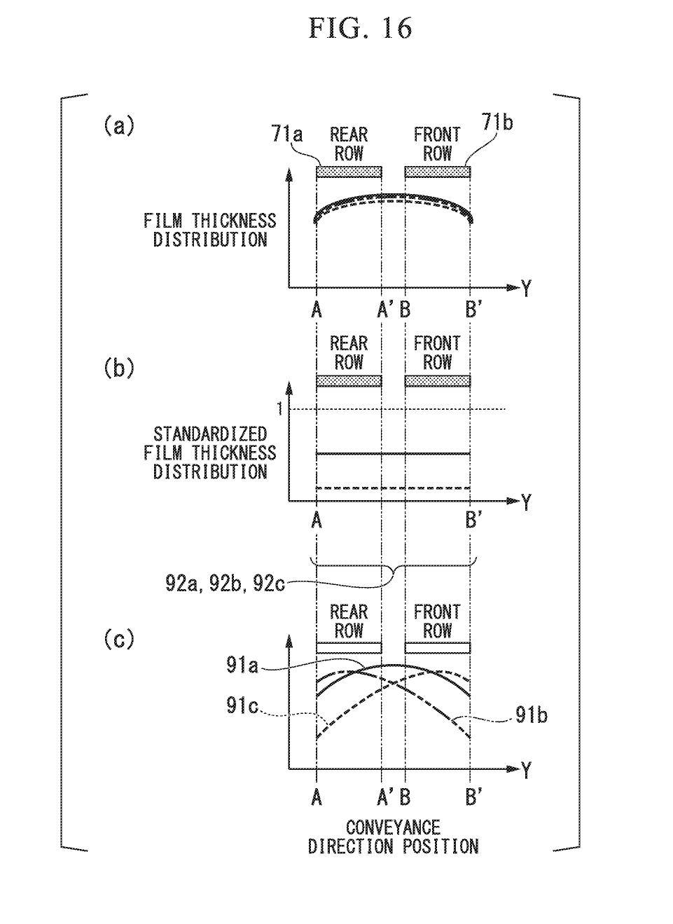

FIG. 13 is a view along a surface passing through a vapor deposition source opening perpendicular to a running direction of a substrate of a vapor deposition device according to an embodiment, showing a front cross-sectional view along a surface parallel to the moving direction 10a of the substrate 10 showing an aspect in which the coat 90 is formed on the substrate 10, FIG. 14 is a plan view showing a vapor deposition source opening of the vapor deposition device shown in FIG. 13, FIG. 15 is a plan view showing a vapor deposition mask opening of the vapor deposition device shown in FIG. 13, and FIG. 16 is a graph showing setting conditions of the vapor deposition source opening of the vapor deposition device shown in FIG. 14, FIG. 16(a) showing a graph of a film thickness distribution in a substrate conveyance direction due to the vapor deposition source opening of the embodiment, FIG. 16(b) showing a graph of a standardized film thickness distribution in the substrate conveyance direction due to the vapor deposition source opening of the embodiment, and FIG. 16(c) showing a graph of a standardized film thickness distribution in a substrate conveyance direction by a vapor deposition source opening in the related art.

The third embodiment is distinguished from the above-mentioned second embodiment in that a means configured to correct the film thickness distribution relates to a shape of the vapor deposition source opening, and components corresponding to the others are designated by the same reference numerals and description thereof will be omitted.

In the embodiment, either of the second and third vapor deposition source openings 61b and 61c disposed at front and rear sides in the conveyance direction are set with respect to the first vapor deposition source opening 61a of the center such that the second region 92b and the third region 92c overlap the first region 92a and the radiation angle of the second and third vapor deposition particles 91b and 91c is inclined closer to the first vapor deposition source openings 61a than that of the radiation angle of the first vapor deposition particles 91a.

Accordingly, the first to third vapor deposition particles 91a, 91b and 91c discharged from the vapor deposition source openings 61a, 61b and 61c advance in a radial direction set to the openings, respectively. The disposition of the limit plate unit 80 is appropriately set correspondingly to the radiation angles of the second and third vapor deposition particles 91b and 91c and the setting positions of the regions 92a, 92b and 92c.

In addition, the second vapor deposition source openings 61b are opened in the direction inclined toward the rear side in the conveyance direction 10a other than the direction parallel to the Z-axis, and an emission angle of the second vapor deposition particles 91b is restricted by a limiting aperture 81b of the limit plate unit 80 to the direction inclined toward the rear side in the conveyance direction 10a of the Z-axis direction. The third vapor deposition source openings 61c are opened in the direction inclined toward the front side in the conveyance direction 10a other than the direction perpendicular to the Z-axis, and an emission angle of the third vapor deposition particles 91c is restricted by a limiting aperture 81c of the limit plate unit 80 to the direction inclined toward the front side in the conveyance direction 10a other than the Z-axis direction.

The number of the first vapor deposition particles 91a discharged from the first vapor deposition source openings 61a is largest at the center of the first vapor deposition source openings 61a in the opening direction (in the example, in the Z-axis direction) when there is no limit nozzle, and gradually reduced as the angle (the emission angle) formed with respect to the opening direction is increased. That is, the first vapor deposition particles 91a have a distribution in which a peak is provided immediately above the first vapor deposition source openings 61a and decreased forward and rearward in the Y direction (the conveyance direction).

The number of the second vapor deposition particles 91b discharged from the second vapor deposition source openings 61b is largest at the center of the second vapor deposition source openings 61b in the opening direction (in the example, the direction inclined toward the rear side in the conveyance direction 10a from the Z-axis direction) when there is no limit nozzle, and gradually reduced as the angle (the emission angle) formed with respect to the opening direction is increased. That is, the second vapor deposition particles 91b have a distribution in which a peak is provided at a position immediately above a mask opening (a rear row) 71a of a rear side in the Y direction (the conveyance direction) and decreased forward and rearward in the Y direction (the conveyance direction), and is less biased to the direction restricted by the limiting aperture 81b of the limit plate unit 80 (the direction inclined toward the front side in the conveyance direction 10a other than the Z-axis direction).

Similarly, the number of the third vapor deposition particles 91c discharged from the third vapor deposition source openings 61c is largest at the center of the third vapor deposition source openings 61c in the opening direction (in the example, in the direction inclined toward the front side in the conveyance direction 10a from the Z-axis direction) when there is no limit nozzle, and gradually reduced as the angle (the emission angle) formed with respect to the opening direction is increased. That is, the third vapor deposition particles 91c have a distribution in which a peak is provided at a position of a mask opening (a front row) 71b of the front side in the Y direction (the conveyance direction) and decreased forward and rearward in the Y direction (the conveyance direction), and is less biased to the direction restricted by the limiting aperture 81c of the limit plate unit 80 (the direction inclined toward the rear side in the conveyance direction 10a other than the Z-axis direction).

In this way, the distribution of the second vapor deposition particles 91b and the distribution of the third vapor deposition particles 91c are in a state reversed in the Y direction (the conveyance direction), and a difference in magnitude is larger than in the distribution of the first vapor deposition particles 91a.

In the embodiment, as shown in FIG. 14, the first limit nozzles 61a1, 61a2, 61a3, 61a4 and 61a5 separated from each other at five places in the Y direction 10a are installed in the first vapor deposition source openings 61a, the second limit nozzles 61b1, 61b2, 61b3, 61b4 and 61b5 separated from each other at five places in the Y direction 10a are installed in the second vapor deposition source openings 61b, and the third limit nozzles 61c1, 61c2, 61c3, 61c4 and 61c5 separated from each other at five places in the Y direction 10a are installed in the third vapor deposition source openings 61c correspondingly to correct a deviation of the distribution in the first to third vapor deposition particles 91a, 91b and 91c.

In the second vapor deposition source openings 61b, as shown in FIG. 16(c), a state in which the number of the second vapor deposition particles 91b discharged from the second vapor deposition source openings 61b when there is no limit nozzle is increased at the rear side in the conveyance direction other than the center between A-B′ in the Y direction 10a is corrected to obtain a balance of the distribution, and as shown in FIG. 16(a), becomes a shape in which the distribution of the number of the discharged second vapor deposition particles 91b is set such that the distribution between A-B′ in the Y direction 10a is as uniform a profile as possible. That is, the second vapor deposition source openings 61b are set such that the distribution of the number of the second vapor deposition particles 91b standardized with the distribution of the number of the first vapor deposition particles 91a between A-B′ in the Y direction 10a is uniformized between A-B′ as shown in FIG. 16(b).

Specifically, an opening dimension of the second limit nozzle 61b3 immediately above the vapor deposition source in the Y direction 10a is set to be largest, and a total value of opening dimensions in the Y direction of the second limit nozzles 61b1 and 61b2 disposed at the front side in the conveyance direction is set to be smaller than a total value of opening dimensions in the Y direction of the second limit nozzles 61b4 and 61b5 disposed at the rear side in the conveyance direction.

In the third vapor deposition source openings 61c, as shown in FIG. 16(c), a state in which the number of the second vapor deposition particles 91c discharged from the third vapor deposition source openings 61c when there is no limit nozzle is increased at the front side in the conveyance direction other than the center between A-B′ in the Y direction 10a is corrected to obtain a balance of the distribution, and as shown in FIG. 16(a), becomes a shape in which the distribution of the number of the discharged the third vapor deposition particles 91c is set such that the distribution between A-B′ in the Y direction 10a is as uniform a profile as possible. That is, the third vapor deposition source openings 61c are set such that the distribution of the number of the third vapor deposition particles 91c standardized with the distribution of the number of first vapor deposition particles 91a between A-B′ in the Y direction 10a is uniformized between A-B′ as shown in FIG. 16(b).

Specifically, an opening dimension of the third limit nozzle 61c3 immediately above the vapor deposition source in the Y direction 10a is set to be smallest, and a total value of opening dimensions in the Y direction of the third limit nozzles 61c4 and 61b5 disposed at the rear side in the conveyance direction is set to be smaller than a total value of opening dimensions in the Y direction of the second limit nozzles 61c1 and 61c2 disposed at the front side in the conveyance direction.

In the first vapor deposition source openings 61a, as shown in FIG. 16(c), a state in which the number of the first vapor deposition particles 91a discharged from the first vapor deposition source openings 61a when there is no limit nozzle is increased at a center between A-B′ in the Y direction 10a is corrected, and as shown in FIG. 16(a), becomes a shape in which the distribution of the number of the discharged first vapor deposition particles 91a is set such that a difference in distribution between A-B′ in the Y direction 10a is reduced. Specifically, as shown in FIG. 14, an opening dimension of the first limit nozzle 61a3 of the center in the Y direction 10a is set to be smallest, opening dimensions of the first limit nozzles 61a2 and 61a4 disposed at both sides thereof in the Y direction 10a are set to be larger than the first limit nozzle 61a3, and further, opening dimensions of the first limit nozzles 61a1 and 61a5 disposed outside both sides thereof in the Y direction 10a are set to be larger than the first limit nozzles 61a2 and 61a4.

In the embodiment, the first region 92a to which the first vapor deposition particles 91a adhere, the second region 92b to which the second vapor deposition particles 91b adhere, and the first region 92c to which the third vapor deposition particles 91c adhere substantially coincide with each other, and further, as shown in FIGS. 16(a) and 16(b), the coat 90 in which a mixing ratio of the first vapor deposition particles 91a, the second vapor deposition particles 91b and the third vapor deposition particles 91c is constant in the conveyance direction 10a can be formed.

Accordingly, regardless of the positions of the mask openings 71a and 71b in the conveyance direction 10a, the film thickness distribution and the number of particles ratio of the first vapor deposition particles 91a, the second vapor deposition particles 91b and the third vapor deposition particles 91c are constant, and thus, the coat 90 in which the mixing ratio thereof is constant can be easily formed. Accordingly, the host/assist/dopant ratio is constant regardless of the position in the conveyance direction. Accordingly, when the light emitting layers 23R, 23G and 23B are formed according to the embodiment, since the organic EL element having improved and stabilized emission properties and current properties can be formed, a large organic EL display device having good reliability and display quality can be obtained.

In the embodiment, since the directivity of the first to third vapor deposition particles 91a, 91b and 91c toward the substrate 10 in the Y-axis direction is restricted by setting the shapes of the limit nozzles 61a1 to 61c6, and thus, the first region 92a on the substrate 10 to which the first vapor deposition particles 91a adhere, the second region 92b on the substrate 10 to which the second vapor deposition particles 91b adhere and the third region 92c on the substrate 10 to which the third vapor deposition particles 91c adhere when the vapor deposition mask 70 is not provided substantially coincide with each other, it is important to realize uniformization of the number of particles in these regions. Accordingly, even when the mask openings 71a and 71b are disposed in the conveyance direction 10a as the front row/the rear row, regardless of the positions of the mask openings 71a and 71b in the conveyance direction 10a, the host/assist/dopant ratio can be constant. However, the present invention is not limited thereto.

In the embodiment, while only the opening shapes of the limit nozzles 61a1 to 61c6 has been described as being set, there is no limitation thereto and the configuration is not limited as long as the directivity of the first to third vapor deposition particles 91a, 91b and 91c toward the substrate 10 in the Y-axis direction can be controlled and uniformization of the number of particles in the first to third regions 92a, 92b and 92c can be realized.

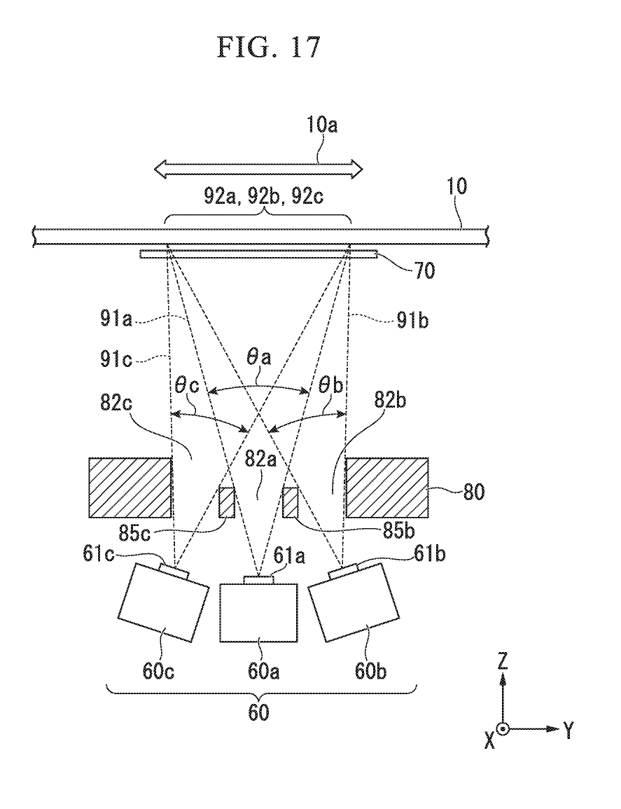

Further, in the embodiment of the present invention, as shown in FIG. 17, a configuration in which the limit plate unit 80 is installed between the vapor deposition source 60 and the mask 70 can be provided. In this case, the vapor deposition unit is constituted by the vapor deposition source 60, the vapor deposition mask 70, and the limit plate unit 80 disposed therebetween.

In the example, similar to the example shown in FIG. 14, while the positions of the first region 92a, the second region 92b and the third region 92c in the Y-axis direction substantially coincide with each other, the second and third vapor deposition source openings 61b and 61c disposed at front and rear sides in the conveyance direction with respect to the first vapor deposition source openings 61a of the center have discharge angles of the second and third vapor deposition particles 91b and 91c set to be inclined inward such that the second region 92b and the third region 92c overlap the first region 92a.

Accordingly, the first to third vapor deposition particles 91a, 91b and 91c discharged from the vapor deposition source openings 61a, 61b and 61c are emitted while maintaining a predetermined distribution in discharge directions. The disposition of the limit plate unit 80 is appropriately set correspondingly to the discharge angles of the second and third vapor deposition particles 91b and 91c and the setting positions of the regions 92a, 92b and 92c.

In this example, similar to the example shown in FIG. 16(c), the first to third vapor deposition particles 91a, 91b and 91c are discharged from the first to third vapor deposition source openings 61a, 61b and 61c with a spread (directivity) in the X-axis direction and the Y-axis direction as they are, respectively, when there are no limit nozzles. In the Embodiment 1, the first vapor deposition source openings 61a are opened in the direction parallel to the Z-axis. In addition, the second vapor deposition source openings 61b and the third vapor deposition source openings 61c are opened in the direction inclined from the Z-axis toward the front and rear sides in the Y direction as described above.

Similar to the example shown in FIG. 16(c), the number of the first vapor deposition particles 91a discharged from the first vapor deposition source openings 61a when there is no limit nozzle is largest at the center of the first vapor deposition source openings 61a in the opening direction (in the example, in the Z-axis direction) and gradually reduced as the angle (the emission angle) formed with respect to the opening direction is increased.

The number of the second vapor deposition particles 91b discharged from the second vapor deposition source openings 61b when there is no limit nozzle is largest in an direction along the opening direction of the second vapor deposition source openings 61b (in the example, the direction inclined toward the rear side in the conveyance direction 10a other than the Z-axis direction), and gradually reduced as the angle (the emission angle) formed with respect to the opening direction is increased.

Similarly, the number of the third vapor deposition particles 91c discharged from the third vapor deposition source openings 61c when there is no limit nozzle is largest in an direction along the opening direction of the third vapor deposition source openings 61c (in the example, the direction inclined toward the front side in the conveyance direction 10a other than the Z-axis direction), and gradually reduced as the angle (the emission angle) formed with respect to the opening direction is increased.

Also in this example, similarly to the example shown in FIG. 14, the limit nozzles separated in the Y direction 10a can be installed in the first vapor deposition source openings 61a to the third vapor deposition source openings 61c correspondingly to the distribution to correct the limit nozzles. In addition, in the example, since the second vapor deposition source openings 61b and the third vapor deposition source openings 61c are inclined inward, when the same separation form as in the example shown in FIG. 14 is provided, further correction may be provided.

Further, a plurality of limiting apertures that are through-holes passing through the limit plate unit 80 in the Z-axis direction are formed in the limit plate unit 80 of the example. The plurality of limiting apertures include a plurality of first limiting apertures 82a disposed along a straight line parallel to the X-axis direction, a plurality of second limiting apertures 82b disposed along another straight line parallel to the X-axis direction, and a plurality of third limiting apertures 82c disposed along another straight line parallel to the X-axis direction. The plurality of third limiting apertures 82c are disposed at a side opposite to plurality of second limiting apertures 82b with respect to the first limiting apertures 82a in the Y-axis direction. The first limiting apertures 82a, the third limiting apertures 82c and the second limiting apertures 82b, which are adjacent to each other in the Y-axis direction, are disposed along another straight line parallel to the Y-axis direction. The first limiting apertures 82a adjacent to each other in the X-axis direction are separated by a first limit plate, the second limiting apertures 82b adjacent to each other in the X-axis direction are separated by a second limit plate, and the third limiting apertures 82c adjacent to each other in the X-axis direction is separated by a third limit plate. The plurality of third limit plates are disposed at a constant pitch in the X-axis direction at the same position as the plurality of second limit plates in the X-axis direction. The first limiting apertures 82a and the second limiting apertures 82b, which are adjacent to each other in the Y-axis direction, are separated by a first partition plate 85b, and the first limiting apertures 82a and the third limiting apertures 82c, which are adjacent to each other in the Y-axis direction, are separated by a second partition plate 85c.

The plurality of first to third limit plates are disposed at a constant pitch in the X-axis direction. The plurality of first limiting apertures 82a, the plurality of second limiting apertures 82b and the plurality of third limiting apertures 82c are disposed at the same position in the X-axis direction. The plurality of first limiting apertures 82a, the plurality of second limiting apertures 82b and the plurality of third limiting apertures 82c are disposed at different positions in the Y-axis direction.

The plurality of vapor deposition source openings 61a, 61b and 61c and the limit plate unit 80 are separated from each other in the Z-axis direction, and the limit plate unit 80 and the vapor deposition mask 70 are separated from each other in the Z-axis direction. Relative positions between the vapor deposition sources 60a, 60b and 61c, the limit plate unit 80 and the vapor deposition mask 70 are preferably substantially constant during a period of performing at least “coating vapor deposition.”

The limit plate unit 80 restricts the directivity of the first to third vapor deposition particles 91a to 91c discharged from the first to third vapor deposition source openings 61a to 61c toward the substrate 10 in the X-axis direction and the Y-axis direction. Accordingly, unnecessary vapor deposition particles can be restricted and desired vapor deposition particles can be attached to only an arbitrary mask opening region.

In the embodiment, when the vapor deposition is performed by disposing the vapor deposition unit in the vapor deposition device such that the Y direction is the scanning direction and relatively moving the substrate 10 with respect to the vapor deposition unit and the vapor deposition source, limit nozzle openings are disposed with an irregular pitch in the conveyance direction, the host that becomes the first vapor deposition particles is divided into five parts in the conveyance direction, the dopant and the assist that become the second vapor deposition particles and the third vapor deposition particles are divided into five parts in the conveyance direction, a nozzle opening width or a distance between the openings is designed such that a film forming distribution in the conveyance direction is aligned with other materials and set to be not uniform, film forming conditions are rate: host material 2 angstrom/s, dopant 1 material 0.3 angstroms/s, assist material 1 angstrom/s, and film thickness: 300 angstroms, the vapor deposition source openings are disposed with an irregular pitch in the conveyance direction 10a of the substrate, the opening pitch is set such that distributions of the host and the dopant are the same, and thus, the film thickness distributions of the host/assist/dopant have the same shape in the conveyance direction.

Here, the disposition of the openings (or shields) at an irregular pitch is not limited to the nozzle opening and may have an aperture shape. In addition, the limit plate is provided to cut out the distribution, the distribution itself is changed in the nozzle, and the difference is considered as a pressure state.

As described above, the host/assist/dopant ratio is constant regardless of the position in the conveyance direction. Accordingly, an effect of eliminating a difference in chromaticity/luminance at a vapor deposition region boundary in the light emitting device can be exhibited.

In addition, in the embodiment, while the limit nozzle openings are disposed in the X direction in the same way, shapes of the limit nozzle openings can be deformed correspondingly to shapes of the vapor deposition masks 70 in a zigzag shape of FIG. 15 and correspond to the front row and the rear row. That is, the mask openings 71a disposed at the row 61A, the row 61C and the row 61E in the Y direction in FIG. 14 may have shapes corresponding to the row 71A, the row 71C and the row 71E in FIG. 15, and the mask openings 71b disposed at the row 61B, the row 61D and the row 61F in FIG. 14 may have shapes corresponding to row 71B, the row 71D and the row 71F in FIG. 15. Accordingly, since the mask openings 71a can control distribution of the vapor deposition particles between A-A′ in the Y direction in FIG. 16 and the mask openings 71b can control distribution of the vapor deposition particles between B-B′ in the Y direction in FIG. 16, while it is necessary to control to balance the distribution difference between A-A′ and B-B′, there is a room for design to enable distribution adjustment of three vapor deposition particles between A-A′ or between B-B′, and improvement of distribution and improvement of material use efficiency are possible.

### INDUSTRIAL APPLICABILITY

While a field of use of the vapor deposition device and the vapor deposition method according to some aspects of the present invention is not particularly limited, the present invention can be preferably used to form a light emitting layer of an organic EL display device.

### DESCRIPTION OF THE REFERENCE SYMBOLS

10 Substrate
10a First direction
20 Organic EL element
23R, 23G, 23B Light emitting layer
56 Moving mechanism
60 Vapor deposition source
61a, 61b, 61c Vapor deposition source opening
61a1 to 61c6 Limit nozzle
70 Vapor deposition mask
71a, 71b Mask opening
92a, 92b, 92c Vapor deposition region
90 Coat
91a, 91b, 91c Vapor deposition particles

1. A vapor deposition device configured to form a coat having a pattern corresponding to an opening shape of a mask opening on a substrate via a vapor deposition mask in which the mask opening is formed,
the vapor deposition device comprising:
a vapor deposition unit having a plurality of vapor deposition sources each having a vapor deposition source opening configured to perform co-vapor deposition with respect to at least the mask opening; and
a moving mechanism configured to relatively move one of the substrate and the vapor deposition unit with respect to the other in a first direction which is an in-plane direction of the substrate,
wherein the plurality of vapor deposition source openings are disposed at different positions from an upstream side in the first direction,
limit nozzles configured to restrict directivity to the in-plane direction of a plurality of vapor deposition particles discharged from the plurality of vapor deposition source openings toward the substrate are installed in the plurality of vapor deposition source openings,
at least a region in which the plurality of vapor deposition particles overlap in a vapor deposition region is provided with respect to the vapor deposition region on the substrate to which the plurality of vapor deposition particles adhere in a case that the vapor deposition mask is not provided, and
the limit nozzles are set to restrict the directivity of the vapor deposition particles in the first direction to reduce differences in density distribution of the vapor deposition particles in the vapor deposition region generated due to the positions of the limit nozzles in the first direction.

2. The vapor deposition device according to claim 1, wherein the plurality of vapor deposition sources comprise first, second and third vapor deposition sources, and the first, second and third vapor deposition sources include first, second and third vapor deposition source openings,
the third, first and second vapor deposition source openings are sequentially disposed at different positions from an upstream side toward a downstream side in the first direction,
first, second and third limit nozzles configured to restrict directivity of first, second and third vapor deposition particles discharged from the first, second and third vapor deposition source openings toward the substrate in the in-plane direction are installed in the first, second and third vapor deposition source openings,
provided that regions on the substrate to which the first vapor deposition particles, the second vapor deposition particles and the third vapor deposition particles adhere are a first region, a second region and a third region, respectively, in a case that the vapor deposition mask is not provided,
discharge directions of the second and third vapor deposition particles are controlled to be inclined to have portions of the first, second and third vapor deposition source openings in which the first region, the second region and the third region overlap each other,
the second limit nozzle reduces the second vapor deposition particles density that is large at the first limit nozzle side of the second region in the first direction by inclining the discharge direction of the second vapor deposition particles toward the first limit nozzle such that the second region overlaps the first region, and reduces a difference of the second vapor deposition particles density in the second region in the first direction and restrict the directivity to decrease a width of the distribution,
the third limit nozzle reduces the third vapor deposition particles density that is large at the first limit nozzle side of the third region in the first direction by inclining the discharge direction of the third vapor deposition particles toward the first limit nozzle such that the third region overlaps the first region, and reduces a difference of the third vapor deposition particles density of the third region in the first direction and restrict the directivity to reduce a width of the distribution,
the first limit nozzle installed in the first vapor deposition source opening restricts the directivity to reduce a difference of the distribution of the first vapor deposition particles that is reduced at an upstream side and a downstream side in the first direction in the first region, and
in the first, second and third limit nozzles, directivity of the first, second and third vapor deposition particles is set to be restricted such that a distribution state of the first, second and third vapor deposition particles density is equalized in the first direction.

3. The vapor deposition device according to claim 2, wherein the limit nozzle is set to restrict the directivity of the first to third vapor deposition particles in the first direction such that positions of the first to third region in the first direction coincide with each other.

4. The vapor deposition device according to claim 2, wherein any one of the first limit nozzle installed in the first vapor deposition source opening, the second limit nozzle installed in the second vapor deposition source opening, and the third limit nozzle installed in the third vapor deposition source opening is disposed by being separated into plural sections in the first direction.

5. The vapor deposition device according to claim 4, wherein the plurality of first to third divided limit nozzles are disposed irregularly in the first direction.

6. The vapor deposition device according to claim 2, wherein the limit nozzles vary sizes of nozzle openings divided in plural by the second limit nozzle at positions in the first direction, are set to restrict the directivity of the second vapor deposition particles to correct a density distribution inclined toward the first vapor deposition source openings adjacent to each other in the first direction in the second region, vary sizes of the nozzle openings divided in plural by the third limit nozzle at positions in the first direction, are set to restrict the directivity of the third vapor deposition particles to correct a density distribution inclined toward the first vapor deposition source openings adjacent to each other in the first direction in the third region, vary sizes of the nozzle openings divided in plural by the first limit nozzle at positions in the first direction, and are set to restrict the directivity of the first vapor deposition particles to correct a density distribution inclined toward the second and third vapor deposition source openings adjacent to each other from a center in the first direction in the first region.

7. A vapor deposition method having a vapor deposition process of attaching vapor deposition particles onto a substrate and forming a coat having a predetermined pattern,
wherein the vapor deposition process is performed using the vapor deposition device according to claim 1.

8. The vapor deposition method according to claim 7, wherein the vapor deposition process is performed using the vapor deposition device according to claim 2, and
the coat includes a portion in which the first vapor deposition particles, the second vapor deposition particles and the third vapor deposition particles are mixed.

9. The vapor deposition method according to claim 8, wherein the vapor deposition process is performed using the vapor deposition device according to claim 2, and
in the coat, a mixing ratio of the first vapor deposition particles, the second vapor deposition particles and the third vapor deposition particles is constant in the first direction.

10. The vapor deposition method according to claim 7, wherein the coat is a light emitting layer of an organic EL element.
